(19) United States
(12) Patent Application Publication
(10) Pub. No.: US 2011/0233625 A1
(43) Pub. Date: Sep. 29, 2011

(54) SEMICONDUCTOR DEVICE AND METHOD FOR MANUFACTURING THE SAME

(75) Inventor: Toyonori ETO, Tokyo (JP)

(73) Assignee: ELPIDA MEMORY, INC., Tokyo (JP)

(21) Appl. No.: 13/053,999

(22) Filed: Mar. 22, 2011

(30) Foreign Application Priority Data
Mar. 23, 2010 (JP) 2010-066108

(51) Int. Cl. H01L 29/772; H01L 23/532; H01L 23/544

(52) U.S. Cl. 257/288; 257/751; 257/620; 257/E23.154; 257/E29.242; 257/E23.179

(57) ABSTRACT

A semiconductor device includes a semiconductor chip; and a scribe line disposed in an adjacent way to and around the semiconductor chip. The scribe line comprises an interlayer insulating film and an accessory. The accessory comprises a first portion with a layer shape formed on the interlayer insulating film and a second portion extending downward from the first portion into the interlayer insulating film in a thickness direction thereof.

This application is based upon and claims the benefit of priority from Japanese Patent Application No. 2010-066108, filed on Mar. 23, 2010, the disclosure of which is incorporated herein in its entirety by reference.

### TECHNICAL FIELD

The invention relates to a semiconductor device and a method for manufacturing the same.

### RELATED ART

Generally, a topmost face of a semiconductor chip has been covered with a protective film such as a polyimide film. After a front-end process (diffusion process) has been completed, a semiconductor chip formed on a semiconductor substrate is divided by dicing thereof along a scribe line (dicing line). A plurality of accessory patterns such as an alignment mark used in an exposure process is provided in the scribe line. As disclosed in Japanese Patent Laid-Open No. 2005-183866, the technique has been known in which a portion of the accessory patterns is covered with a polyimide film, in order to prevent the accessory patterns in the scribe line from peeling off and then scattering during the dicing.

Moreover, when not providing the protective film, the accessory patterns in the scribe line come into being exposed. In particular, in case that the semiconductor chip includes a fuse to be cut by irradiating laser beam thereto, as disclosed in Japanese Patent Laid-Open No. 1999-145192, it is necessary to appropriately control thickness of an interlayer insulating film on the fuse. In connection with this, the accessory patterns in the scribe line are exposed easily.

### SUMMARY OF THE INVENTION

In one embodiment, there is provided a semiconductor device comprising:

a semiconductor chip; and

a scribe line disposed around the semiconductor chip and comprising an interlayer insulating film and an accessory,

wherein the accessory comprises a first portion with a layer shape form ed on the interlayer insulating film and a second portion extending downward from the first portion into the interlayer insulating film in a thickness direction thereof.

In another embodiment, there is provided a semiconductor device comprising:

a semiconductor chip; and

a scribe line disposed in an adjacent way to and around the semiconductor chip and comprising an interlayer insulating film and an accessory,

wherein the accessory comprises a second portion buried in the interlayer insulating film and a first portion with a layer shape formed on the interlayer insulating film so as to be in contact with the second portion.

In another embodiment, there is provided a semiconductor device comprising:

a semiconductor chip; and

a scribe line disposed in an adjacent way to and around the semiconductor chip and comprising an interlayer insulating film and an accessory,

wherein the accessory comprises:

a first portion formed on the interlayer insulating film and extending in a width direction of the scribe line; and

two protruding second portions buried in the interlayer insulating film from both ends of the first portion in the width direction of the scribe line.

In another embodiment, there is provided a method for manufacturing a semiconductor device, comprising:

forming an interlayer insulating film in a scribe line forming region of a semiconductor substrate;

forming a second portion so as to extend downward from a surface of the interlayer insulating film into the interlayer insulating film in a thickness direction thereof; and

forming a first portion with a layer shape on the interlayer insulating film so as to be in contact with the second portion, to provide an accessory including the first and second portions.

### BRIEF DESCRIPTIONS OF THE DRAWINGS

The above features and advantages of the present invention will be more apparent from the following description of certain preferred embodiments taken in conjunction with the accompanying drawings, in which:

FIGS. 1 to 13 illustrate a method for manufacturing a semiconductor device according to a first exemplary embodiment of the invention;

FIGS. 14 to 15 illustrate a method for manufacturing a semiconductor device according to a second exemplary embodiment of the invention;

FIGS. 16 to 20 illustrate a method for manufacturing a semiconductor device according to a third exemplary embodiment of the invention;

FIGS. 21 to 24 illustrate a method for manufacturing a semiconductor device according to a fourth exemplary embodiment of the invention;

FIG. 25 to 37 illustrate a method for manufacturing a semiconductor device according to a fifth exemplary embodiment of the invention;

FIG. 38 illustrates a semiconductor device according to the first exemplary embodiment.

In the drawings, reference numerals have the following meanings: 1: MOS transistor, 2: first wire, 3: first contact plug, 4: first interlayer insulating film, 5: isolation region, 6: semiconductor substrate, 7: second contact hole, 8: second interlayer insulating film, 9: second contact plug, 10: second wire, 11: third contact hole, 13: third interlayer insulating film, 14: accessory hole, 15: third contact plug, 17: third wire, 18, 35, 36: accessory, 18a: first portion, 18b: accessory hole buried portion, 19: pad, 20: scribe line opening, 21: passivation film, 22: protective film, 23: pad opening, 24: scribe line, 25: depressed portion a, 26: fuse, 27: fuse opening, 29: first intermediate insulating film, 30: first stopper layer, 31: second stopper layer, 37: dicing-cut portion, 40: semiconductor chip, 41: width direction of the scribe line, 42: perpendicular direction to the width direction of the scribe line

### DETAILED DESCRIPTION OF EXEMPLARY EMBODIMENT

A semiconductor device and a method for manufacturing the same include an accessory in a scribe line and forming the same, respectively. The accessory includes a first portion having a layer shape formed on an interlayer insulating film and a second portion (hereinafter, frequently referred to as “an accessory hole buried portion”). The second portion is bonded to the first portion and is buried in the interlayer insulating film. The first portion is rigidly fixed to a semiconductor chip with the second portion.

Therefore, the first portion is prevented from peeling off due to a stress resulting from a dicing process for dividing the semiconductor chip or from an assembling process after the dicing process. Because of this, the accessory is prevented from scattering during the dicing process or the assembling process. A short circuit between pads resulting from the peel off and scatters of the firs portion is prevented. As a result, reduction of yield of a semiconductor device is suppressed. Moreover, it is not necessary to cover a portion of the accessory pattern with a protective film and hence the scribe line with a small width may be used so that it is possible to increase a number of semiconductor chips disposed on one piece of a semiconductor substrate.

The invention will be now described herein with reference to illustrative embodiments. Those skilled in the art will recognize that many alternative embodiments can be accomplished using the teachings of the present invention and that the invention is not limited to the embodiments illustrated for explanatory purpose.

### First Exemplary Embodiment

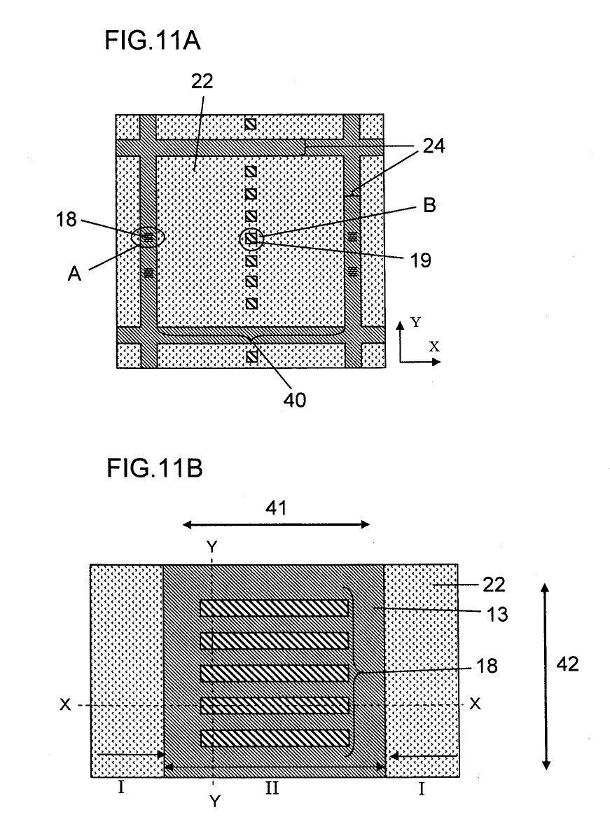

FIGS. 11 to 13 illustrate a completed semiconductor device according to a first exemplary embodiment. Below, a structure of the semiconductor device according to this exemplary embodiment will be described with reference to those drawings.

FIG. 11A is a top view of one region of a surface of a semiconductor substrate as viewed from a top of the semiconductor substrate. As shown in FIG. 11A, scribe lines 24 are intersected so as to form a lattice shape. Scribe lines 24 are used as cutting lines when cutting and dividing the semiconductor chip formed on the semiconductor substrate. Semiconductor chip 40 with a rectangular shape is formed in a device forming region partitioned with scribe lines 24. A plurality of pads 19 are formed on semiconductor chip 40. Each of wire lines to be connected to external terminals using a bonding apparatus is adhered in a pressed way to each of pads 19 respectively in the assembling process of the semiconductor device.

The surface of semiconductor chip 40 is covered with protective film (polyimide film) 22. At regions corresponding to pads 19, protective film 22 and passivation layer 21 beneath protective film 22 are opened so as to expose top faces of pads 19. Regions at which pads 19 are formed are called “regions B”. As not shown in FIG. 11A, devices such as MOS transistors may be formed on the main surface of semiconductor chip 40.

Third interlayer insulating film 13 is formed on top faces of scribe lines 24. On scribe lines 24 regions, accessory pattern 18 including a plurality of the accessories made of the third wire is exposed. In this exemplary embodiment, accessory pattern 18 is used as an alignment marker in an exposure process. A region which includes accessory pattern 18 and portion of device forming region 40 adjacent to accessory pattern 18 is called “region A”.

FIG. 11B is an enlarged view of region A in FIG. 11A. As shown in FIG. 11B, top faces of scribe lines 24 are made of third interlayer insulating film 13. In this exemplary embodiment, each of scribe lines 24 has 80 μm of a width. The width of each of scribe lines 24 is not limited thereto but may be further smaller depending on a width of a blade of an apparatus used in the dicing process and an alignment precision.

The wire patterns are arranged in perpendicular direction 42 to width direction 41 of scribe line 24 so as to be parallel with each other in scribe line 24. Each of the wire patterns includes a plurality of the third wires, each of which has a rectangular shape extending in width direction 41 of scribe line 24. In this exemplary embodiment, each of the wire patterns has 60 μm size in width direction 41 and has 1 μm size in perpendicular direction 42 and a space between them has 2 μm size in perpendicular direction 42. In this exemplary embodiment, accessory 18 is placed so that both ends thereof are equally distant from light and left edges of scribe line 24 respectively. Although in the exemplary embodiment, each of the wire patterns has 60 μm size in width direction 41, such a width may vary depending on the width of scribe line 24. The top face of the device forming region adjacent to left and right edges of the scribe line 24 is covered with protective film 22.

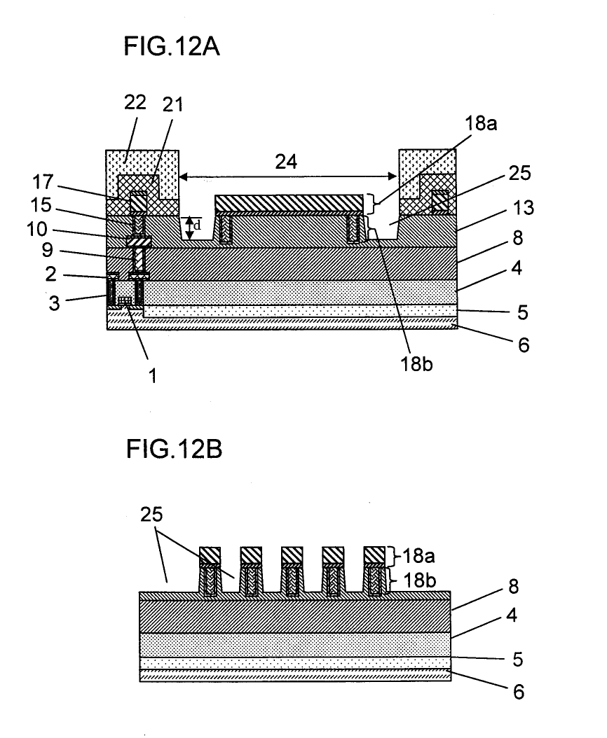

FIGS. 12A and 12B are cross-sectional views taken respectively at an X-X line and in a Y-Y line in FIG. 11B. As shown in FIGS. 12A and 12B, isolation region 5 and an active region are formed on semiconductor substrate 6. In the active region in semiconductor substrate 6, there is formed device 1 such as a MOS transistor. The MOS transistor includes a gate insulating film formed in a surface of semiconductor substrate 6, a gate electrode formed on the gate insulating film and source and drain diffusion layers which are adjacent to the gate electrode and are formed in the surface region of the semiconductor substrate.

First interlayer insulating film 4 is formed on the gate electrode. A thickness of first interlayer insulating film 4 may be approximately 1 μm. First contact plugs 3 are formed so as to penetrate through first interlayer insulating film 4 and connect to the source and drain diffusion layers. First contact plug 3 may include an underlying layer (barrier layer) made of a stack of a titanium (Ti) film and a titanium nitride (TiN) film and a core layer made of a tungsten (W) film.

First wire 2 formed on first contact plug 3 includes a first wire underlying layer made of a stack of a titanium (Ti) film and a titanium nitride (TiN) film, a first primary wire layer made of an aluminum alloy film on the first wire underlying layer and a first cap layer made of a titanium nitride film on the first primary wire layer. Thicknesses of the first wire underlying layer, the first primary wire layer and the first cap layer may be 25 nm, 300 nm and 25 nm respectively.

Second interlayer insulating film 8 is formed on first wire 2. A thickness of second interlayer insulating film 8 becomes 1 μm. Second contact plug 9 is formed so as to penetrate through second interlayer insulating film 8 and connect to first wire 2. Second contact plug 9 may include an underlying layer made of a titanium nitride (TiN) film and a core layer made of a tungsten (W) film.

Second wire 10 formed on second contact plug 9 includes a second wire underlying layer made of a stack of a titanium (Ti) film and a titanium nitride (TiN) film, a second primary wire layer made of an aluminum alloy film on the second wire underlying layer and a second cap layer made of a titanium nitride film on the second primary wire layer. Thicknesses of the second wire underlying layer, the second primary wire layer and the second cap layer may be 25 nm, 300 nm and 25 nm respectively.

Third interlayer insulating film 13 is formed on second wire 10. A thickness of third interlayer insulating film 13 becomes 1 μm. Third contact plug 15 is formed so as to penetrate through third interlayer insulating film 13 and connect to second wire 10. Third contact plug 15 may include a third contact plug underlying layer made of a titanium nitride (TiN) film and a third contact plug core layer made of a tungsten (W) film. In the scribe line 24 region, there is formed accessory hole buried portion (corresponding to a second portion) 18b made of the same material as that of third contact plug 15.

Third wire 17 formed on third contact plug 15 includes a third wire underlying layer made of a stack of a titanium (Ti) film and a titanium nitride (TiN) film, a third primary wire layer made of an aluminum alloy film on the third wire underlying layer and a third cap layer made of a titanium nitride film on the third primary wire layer. Thicknesses of the third wire underlying layer, the third primary wire layer and the third cap layer may be 30 nm, 1 μm and 50 nm respectively.

In the scribe line 24 region, there is formed a portion with a layer shape (corresponding to a first portion) 18a which connects to accessory hole buried portion 18b and includes the third wire underlying layer and the third primary wire layer of third wire 17. A plurality of the first portions are arranged so as to be equally spaced from each other to form the accessory pattern. Accessory hole buried portions 18b are connected to and beneath both ends of the first portion. A combination of first portion 18a and second portions 18b becomes the accessory.

Passivation film 21 is formed on third wire 17. Passivation film 21 is made of a silicon oxynitride (SiON) film and has a thickness of 500 nm. Protective film 22 is formed on passivation film 21. Protective film 22 is made of polyimide resin and has a thickness of 5 μm.

Protective film 22 and passivation film 21 are removed in the scribe line 24 region. Furthermore, in regions of the scribe line 24 at which the accessory does not exist, third interlayer insulating film 13 is depressed by a depth d in a height direction. The depressed portion belonging to third interlayer insulating film 13 region is called “depressed portion a” (indicated as reference numeral 25 in the drawings). In the scribe line 24 region at which the accessory is formed, third interlayer insulating film 13 in the scribe line 24 is not depressed and the first portion of the accessory has a columnar shape protruding in the height direction. The first portion has approximately 1 μm of a width and 1080 nm of a height so as to have the columnar shape longer in the height direction than in the width direction. The first portion has substantially the same height at that of third wire 17 in the device forming region protected with protective film 22.

Herein, the accessory refers to an alignment marker including first portion 18a and accessory hole buried portion 18b. Meanwhile, the accessory is not limited to this but may include a size measurement pattern used in measuring a size of a third wire pattern.

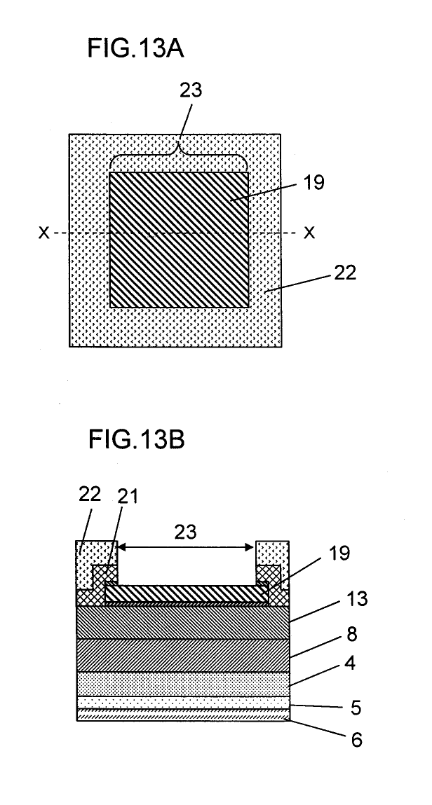

FIG. 13A is an enlarged view of pad region B in FIG. 11A and FIG. 13B is a cross-sectional view taken in a line X-X in FIG. 13A. As shown in FIGS. 13A and 13B, on third interlayer insulating film 13, there are is formed pad 19 including a third wire underlying layer, a third primary wire layer and a third cap layer made of the same material as in third wire 17. Passivation film 21 and protective film 22 are formed on pad 19 so as to be removed on the top face of pad 19, thereby forming pad opening 23. The top face of the pad is exposed with pad opening 23 and the third cap layer is removed on the top face of the pad and thus the third primary wire layer is exposed. In this exemplary embodiment, pad 19 has a square shape with one side length of approximately 60 μm when viewed from a top thereof.

As for first, second, third wires 2, 10, 17, in order to improve reliability such as electro-migration property and suppress light reflection in the exposure process using a lithography technique, the cap layer made of the titanium nitride film is formed on the primary wire layer made of the aluminum alloy film. Because the titanium nitride film forming the cap layer has inferior bonding ability, however, the third cap layer is not formed in the pad opening.

Protective film 22 in region B is opened at the same time when protective film 22 in the scribe line 24 region is opened as shown in FIGS. 12A and 12B. Such an opening of the protective film in the scribe line region prevents the protective film from being attached to the blade and then clogging the blade and thus causing dicing errors or accelerating wearing of the blade during the dicing process for dividing the semiconductor chip. Since the protective film has been removed in the scribe line region, passivation film 21 is removed in the scribe line region at the same time when passivation film 21 is removed on pad 19. With over-etching in removing the passivation film, third interlayer insulating film 13 is etched away and thus the third interlayer insulating film is depressed by the depth d in the scribe line region.

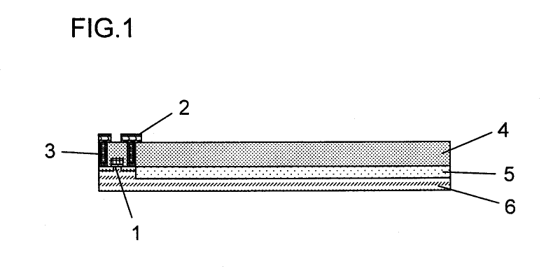

Below, a method for manufacturing the semiconductor device according to this exemplary embodiment will be described with reference to FIGS. 1 to 10.

FIG. 1 illustrates a cross section corresponding to in FIG. 12A. As shown in FIG. 1, isolation region 5 is formed on semiconductor substrate 6 made of silicon. MOS transistor 1 is formed in the active region partitioned with isolation region 5.

The Gate insulating film and gate electrode film are formed on semiconductor substrate 6. The gate electrode is formed by patterning the gate electrode film. The source and drain diffusion layers are formed by doping impurities into regions of semiconductor substrate 6 adjacent to the gate electrode, thereby forming MOS transistor 1.

First interlayer insulating film 4 is formed on the gate electrode using a silicon oxide (SiO₂) film. A thickness of first interlayer insulating film 4 becomes 1 μm. First contact plugs 3 are formed so as to penetrate through first interlayer insulating film 4 and connect to the source and drain diffusion layers. First contact plug 3 may include an underlying layer (barrier layer) made of a stack of a titanium (Ti) film and a titanium nitride (TiN) film and a core layer made of a tungsten (W) film.

First wire 2 is formed on first contact plug 3. First wire 2 is produced by forming on the first contact plug a first wire underlying layer made of a stack of a titanium (Ti) film and a titanium nitride (TiN) film, and then a first primary wire layer made of an aluminum alloy film on the first wire underlying layer and next a first cap layer made of a titanium nitride film on the first primary wire layer, and by patterning the resulting stack structure. Thicknesses of the first wire underlying layer, the first primary wire layer and the first cap layer may be 25 nm, 300 nm and 25 nm respectively. Meanwhile, the first wire underlying layer may be made of a single film such as the titanium nitride film.

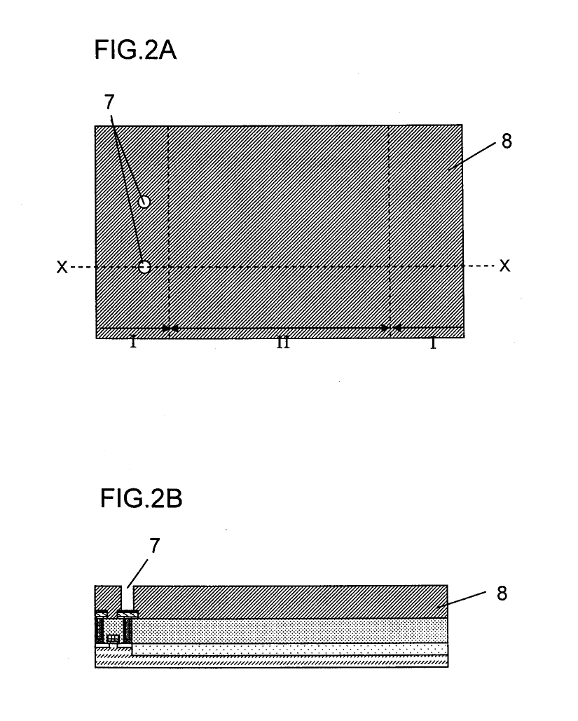

FIG. 2A illustrates a drawing corresponding to FIG. 11B, and FIG. 2B is a cross-section view taken at a line X-X in FIG. 2A. As shown in FIG. 2, second interlayer insulating film 8 is formed on first wire 2 using a silicon oxide (SiO₂) film. A thickness of second interlayer insulating film 8 becomes 1 μm. Second contact hole 7 is formed so as to penetrate through second interlayer insulating film 8 and expose first wire 2.

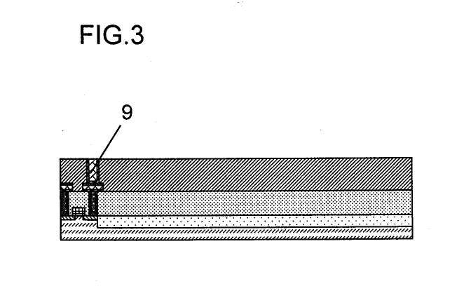

FIG. 3 illustrates a cross section corresponding to FIG. 12A. As shown in FIG. 3, an underlying layer made of a titanium nitride (TiN) film and a tungsten (W) film is formed so as to fill second contact hole 7 and cover second interlayer insulating film 8. Then, using a CMP (chemical mechanical polishing) method, the W film and TiN film on second interlayer insulating film 8 are polished and removed away to form in second contact hole 7 second contact plug 9 including the underlying layer made of the titanium nitride (TiN) film and the tungsten (W) film.

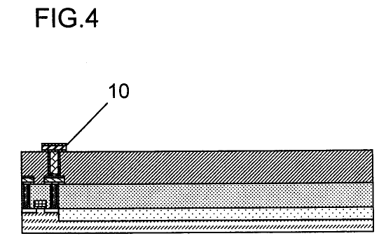

FIG. 4 illustrates a cross section corresponding to FIG. 12A. As shown in FIG. 4, second wire 10 is formed on second contact plug 9. Second wire 10 is produced by forming on second contact plug 9 a second wire underlying layer made of a stack of a titanium (Ti) film and a titanium nitride (TiN) film, and then a second primary wire layer made of an aluminum alloy film on the second wire underlying layer and next a second cap layer made of a titanium nitride film on the second primary wire layer, and by patterning the resulting stack structure.

Thicknesses of the second wire underlying layer, the second primary wire layer and the second cap layer may be 25 nm, 300 nm and 25 nm respectively. Meanwhile, the second wire underlying layer may be made of a single film such as the titanium nitride film.

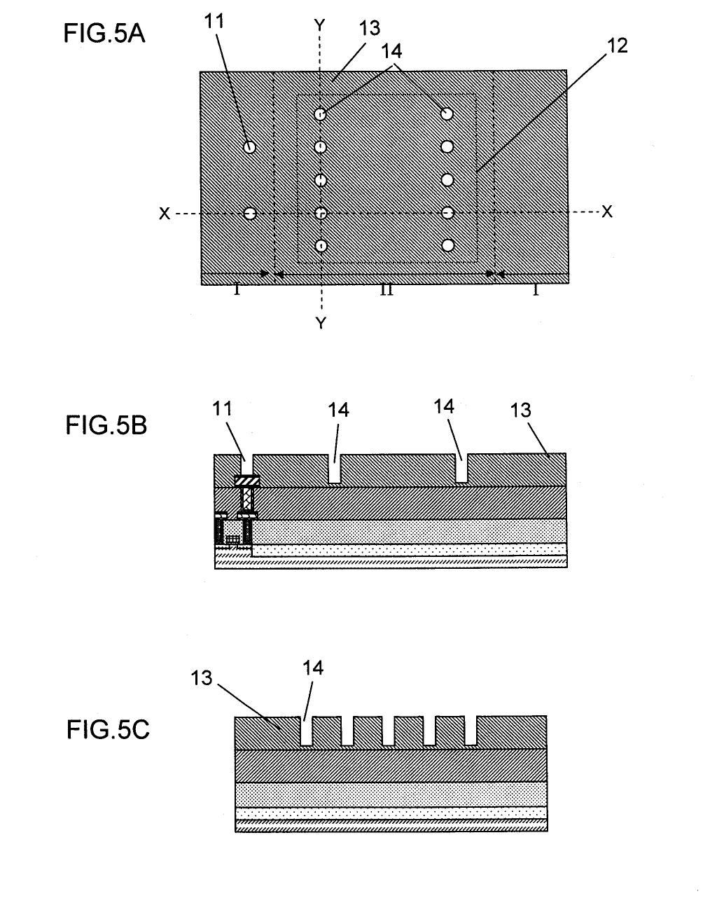

FIG. 5A illustrates a drawing corresponding to FIG. 11B, and FIG. 5B and FIG. 5C are cross-section views taken at a line X-X and a line Y-Y respectively in FIG. 5A. As shown in FIG. 5A, third interlayer insulating film 13 is formed on second wire 10 using the silicon oxide film. A thickness of third interlayer insulating film 13 becomes 1 μm.

Next, using photolithography and dry etching techniques, third contact hole 11 penetrating through third interlayer insulating film 13 and exposing the top face of second wire 10 is formed in the device forming region, and accessory holes 14 are formed in third interlayer insulating film 13 and at regions at which accessories will be formed in the scribe line. In forming third contact hole 11 using the dry etching technique, an over-etching is carried out after the top face of the second wire 10 has been exposed. Accordingly, in that the etching is further proceeding downward at the accessory holes 14 during the over-etching, depths of accessory holes 14 become larger than that of third contact hole 11. Although in FIG. 5, the accessory holes are formed in third interlayer insulating film 13 in such a way not to reach second interlayer insulating film 8, the accessory holes may be formed so as to penetrate through third interlayer insulating film 13 and reach second interlayer insulating film 8.

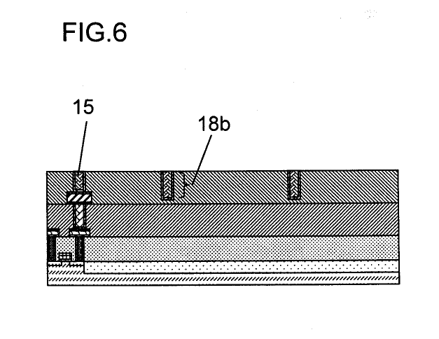

Here, it is preferable that a diameter of third contact hole 11 is equal to diameters of accessory holes 14. By making the diameters uniform in that way, it is easy to bury plug material into second contact hole 11 to form the contact plug as will be described in FIG. 6. Meanwhile, as long as there are no problems regarding the burying of the contact plug material in the following FIG. 6 process, the diameter of third contact hole 11 may be not equal to the diameters of accessory holes 14.

FIG. 6 illustrates a cross section corresponding to FIG. 12A. As shown in FIG. 6, a third contact plug underlying layer made of a titanium nitride (TiN) film and a third contact plug core layer made of a tungsten (W) film are formed so as to fill the accessory holes and the third contact hole and cover third interlayer insulating film 13. Then, the third contact plug underlying layer and the third contact plug core layer on third interlayer insulating film 13 are polished and removed away using the CMP method, thereby forming third contact plug 15 in third contact hole 11 and accessory hole buried portions (corresponding to the second portions) 18b in accessory holes 14.

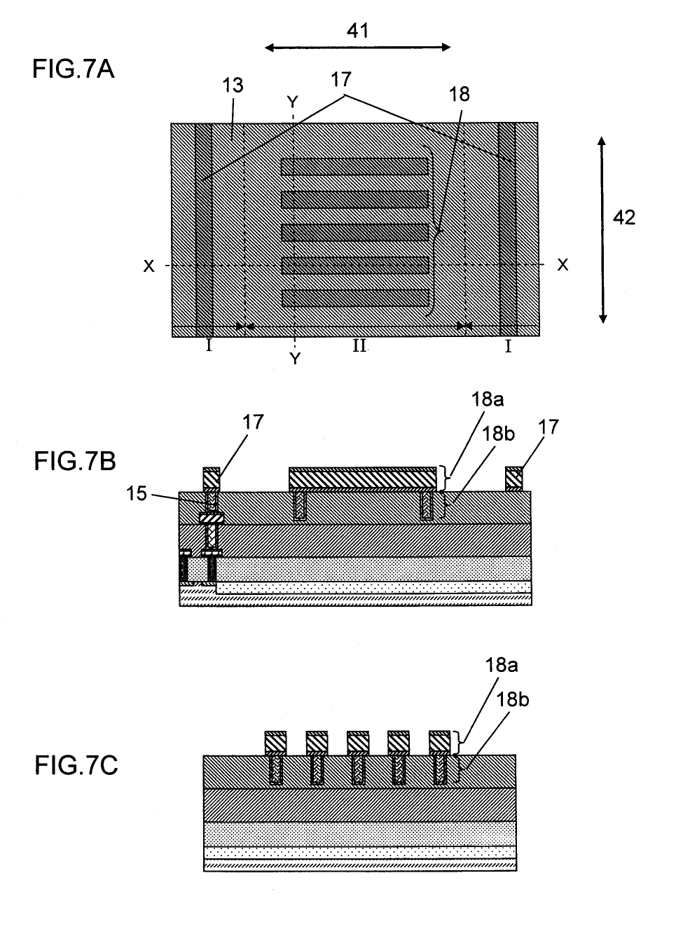

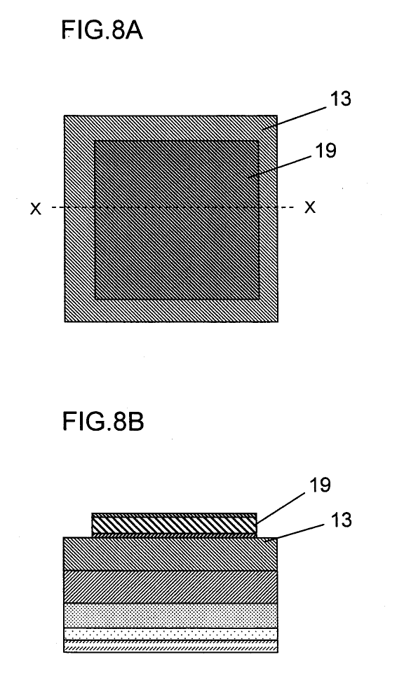

FIG. 7A illustrates a drawing corresponding to FIG. 11B, and FIG. 7B and FIG. 7C are cross-section views taken at a line X-X and a line Y-Y respectively in FIG. 7A. FIG. 8A illustrates a drawing corresponding to FIG. 13A, and FIG. 8B is a cross-section view taken at a line X-X in FIG. 8A. As shown in FIG. 7, a third wire film made of metal is formed on third interlayer insulating film 13 including third contact plug 15 and accessory hole buried portions 18b by forming a third wire underlying layer made of a stack of a titanium (Ti) film and a titanium nitride (TiN) film, and then a third primary wire layer made of an aluminum alloy film on the third wire underlying layer and next a third cap layer made of a titanium nitride film on the third primary wire layer. Thicknesses of the third wire underlying layer, the third primary wire layer and the third cap layer may be 30 nm, 1 μm and 50 nm respectively. Meanwhile, the third wire underlying layer may be made of a single film such as the titanium nitride film. The aluminum alloy film becomes an Al film containing copper (Cu).

Next, using photolithography and dry etching techniques, the resulting third wire film is patterned to form third wire 17 connected to third contact plug 15, first portion 18a connected to accessory hole buried portions 18b and pads 19 at the same time.

As shown in FIG. 7A, third wire 17 is connected to third contact plug 15 and extends in perpendicular direction 42 to width direction 41 of the scribe line. Each of accessory 18 has 60 μm size in width direction 41 and has 1 μm size in perpendicular direction 42 and a space between them has 2 μm size in perpendicular direction 42. As shown in FIG. 7B, accessory hole buried portions 18b are connected to and beneath both ends in width direction 41 of scribe line. As shown in FIG. 7C, the first portion has approximately 1 μm of a width and 1080 nm of a height and thus has approximately 1 of an aspect ratio.

As described above, accessory hole buried portions 18b are formed in and beneath both ends of first portion 18a extending in width direction 41 of scribe line. This is because in a center region of the scribe line, a region corresponding to a width of the blade is cut out and removed away in the dicing process. Since accessory hole buried portions 18b are formed in and beneath both ends of first portion 18a, accessory hole buried portions 18b may remain after the dicing process. For that reason, accessory hole buried portions 18b are formed in regions far away from the center region of scribe line 24 so as not to be placed within the width of the blade during dicing. For example, if the width of the blade becomes WB, accessory hole buried portions 18b are placed at positions far away from the center of the scribe line by a distance equal to or longer than WB/2 distance.

In this exemplary embodiment, the width of the blade becomes 30 μm and accordingly accessory hole buried portions 18b are placed at positions far away from the center of scribe line 24 by a distance equal to or longer than 15 μm. Meanwhile, with consideration of a positional deviation in the dicing process, it is preferable that accessory hole buried portions 18b are placed at positions further far away from the center of the scribe line.

FIGS. 8A and 8B show region B in which the pad is formed. Pad 19 has a square shape with one side length of approximately 60 μm when viewed from a top thereof.

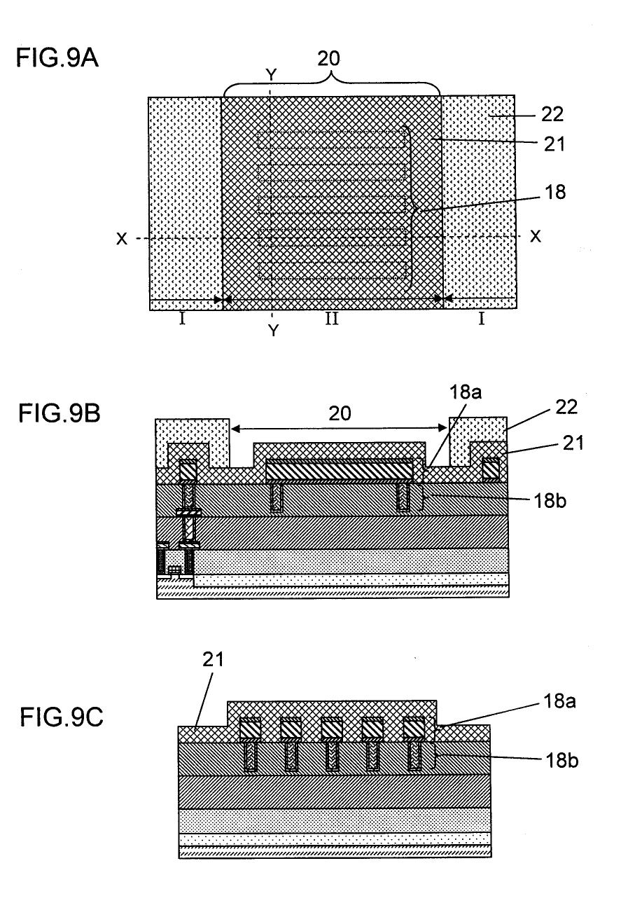

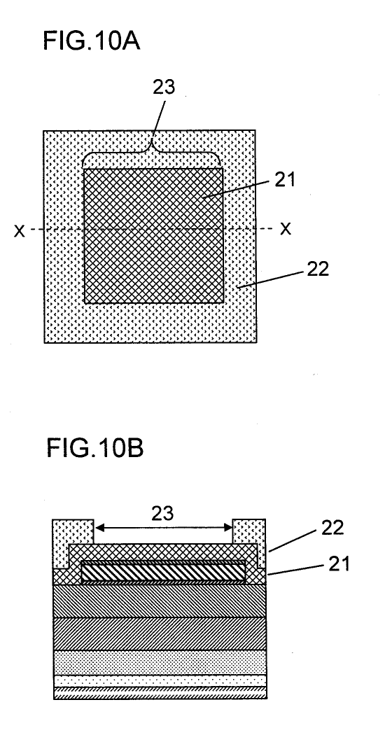

FIG. 9A illustrates a drawing corresponding to FIG. 11B, and FIGS. 9B and 9C are cross-section views taken at a line X-X and a line Y-Y respectively in FIG. 9A. FIG. 10A illustrates a drawing corresponding to FIG. 13A, and FIG. 10B is a cross-section view taken at a line X-X in FIG. 10A. As shown in FIGS. 9 and 10, passivation film 21 with 500 nm thickness is formed using the silicon oxynitride (SiON) film. Protective film 22 with 5 μm thickness is formed using the polyimide resin film. Here, photosensitive polyimide resin film is employed.

The polyimide resin film is subjected to the exposure treatment and an opening is formed in the protective film, resulting in that the top face of passivation film 21 is exposed. The opening includes pad opening 23 (refer to FIG. 10B) exposing the top face of pad 19 and scribe line opening 20 (refer to FIG. 9B) exposing the scribe line.

Here, the reason for which protective film 22 is removed in the scribe line region to form scribe line opening 20 is to prevent the protective film from being attached to the blade and then clogging the blade and thus causing dicing errors or accelerating wearing of the blade during the dicing process for dividing the semiconductor chip.

Although in the above example, the photosensitive polyimide resin film is employed as protective film 22, a non-photosensitive polyimide resin film may be employed. In the latter case, a photoresist mask is formed on the non-photosensitive polyimide resin film and then the polyimide film is etched away using the photoresist mask as a mask, thereby forming the openings.

As shown in FIG. 11 to FIG. 13, passivation film 21 is etched away using protective film 22 as a mask (this etching is referred to as “passivation film etching), and hence the top face of pad 19 is exposed (refer to FIG. 13A and FIG. 13B).

In order to securely expose the top face of pad 19, the passivation film etching is performed in an over-etching manner so that approximately 100% of the film thickness of the passivation film is etched away. During the over-etching, the third cap layer forming the upper portion of the pad is removed away to expose the third primary wire layer. In order to improve reliability such as electro-migration property of wire and suppress light reflection in the exposure process using a lithography technique, the cap layer is formed on the primary wire layer. Since the titanium nitride film forming the cap layer has inferior bonding ability, the third cap layer has been removed away in the passivation film etching.

With the passivation film etching, accessory patterns 18 are exposed in the scribe line 24 region. Third interlayer insulating film 13 is depressed with the further over-etching. A position of the surface of third interlayer insulating film 13 in the scribe line 24 region is lower in a depressed way by the depth d than a position of the surface of third interlayer insulating film 13 in the device forming region in which the protective film 22 is formed. The portion depressed by the depth d is called “depressed portion a” (indicated as reference numeral 25 in FIG. 12A). As pad 19, the third cap layer in accessory patterns 18 is removed to expose the third primary wire layer (refer to FIGS. 12A and 12B).

Third interlayer insulating film 13 beneath accessory pattern 18 is not subjected to the etchant in the etching process and therefore is not removed. Consequently, in the scribe line 24 region, there is formed a pillar shape structure including first portion 18a as its topmost layer and third interlayer insulating film 13 as an underlying layer. Here, depth d becomes approximately 500 nm. As shown in FIGS. 12A and 12B, in the cross-section of the accessory in the short side edge direction thereof, there is formed the pillar shape structure with approximately 1.5 μm height consisted of 1080 nm of the total film thickness of the first portion and 500 nm of the depth of the depressed portion of third interlayer insulating film 13.

There is formed first portion 18a including the third wire underlying layer made of a stack of a titanium (Ti) film and a titanium nitride (TiN) film and a third primary wire layer made of an aluminum alloy film on the third wire underlying layer. There is formed accessory hole buried portion (corresponding to the second portion) 18b including a third contact plug underlying layer made of a titanium nitride (TiN) film and a third contact plug core layer made of a tungsten (W) film on the third contact plug underlying layer so that the accessory hole buried portion connects to the lower portion of first portion 18a. Accessory hole buried portions 18b are buried in both end regions of first portion 18a far away by approximately 30 μm from the center region of scribe line 24 with 80 μm width.

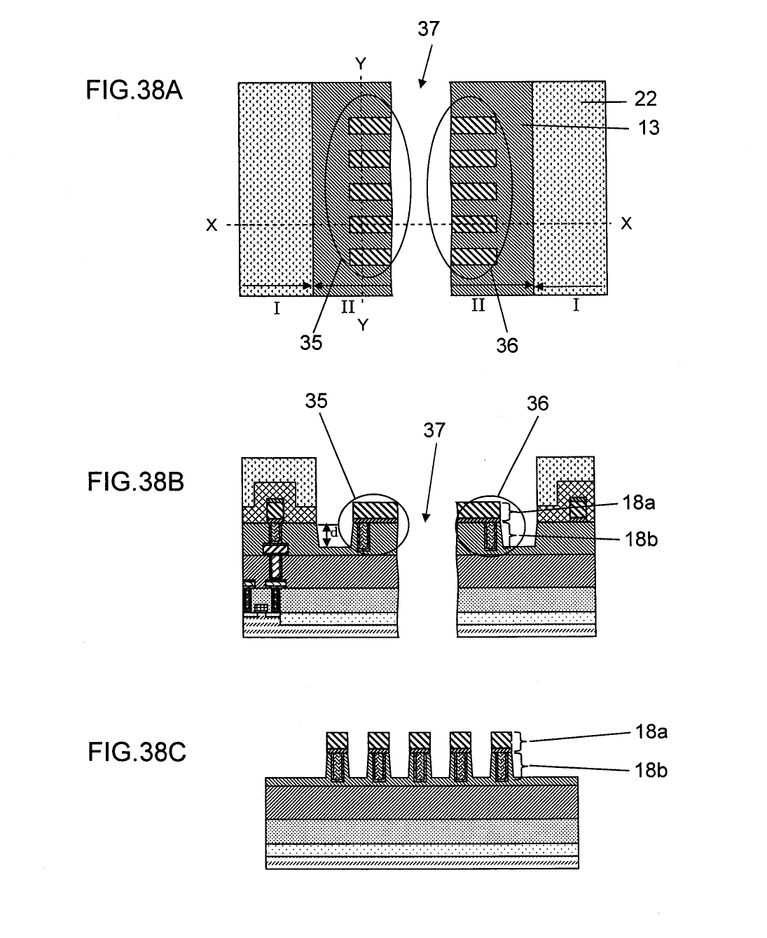

FIG. 38A illustrates a region corresponding to FIG. 11B after the dicing process. The semiconductor chip is divided with the center of the scribe line using the blade with WB=30 μm width. There is formed dicing-cut portion 37 having approximately 30 μm width in the width direction of the scribe line. Accessory patterns 35, 36 remain respectively in the left and right of dicing-cut portion 37. FIG. 38B is a cross-sectional view taken at a line X-X in FIG. 38A.

FIG. 38C is a cross-sectional view taken at a line Y-Y in FIG. 38A. The accessory pattern formed in scribe line 24 is exposed because in case that the accessory hole buried portion is not formed, the overlying passivation film and protective film are removed. Accordingly, there is the problem that the first portion peels off due to a stress resulting from a dicing process for dividing the semiconductor chip or from an assembling process after the dicing process, resulting in scatters of the accessory. Since the scattered first portion has conductive property, there is the problem that the short circuit between the pads occurs, resulting in the reduction of yield of the semiconductor device. In the present exemplary embodiment, however, accessory hole buried portion 18b with a plug shape made of the metal film is buried in third interlayer insulating film 13 and then first portion 18a including the metal film as its lower face is formed on third interlayer insulating film 13 so as to connect to accessory hole buried portion 18b. As a result, the first portion is rigidly fixed to third interlayer insulating film 13 by accessory hole buried portion 18b which has superior adherence property to the lower face of the first portion. The first portion is prevented from peeling off from the top face of third interlayer insulating film 13. Accordingly, the accessory is prevented from peeling off and then scattering due to the stress resulting from the dicing process for dividing the semiconductor chip or from the assembling process after the dicing process.

In the present exemplary embodiment, in order that accessory hole buried portions 18b may remain in the scribe line after the dicing process, accessory hole buried portions 18b are disposed at the regions beyond the blade width used in the dicing process while the center of the blade width is aligned with the width center of scribe line 24. For example, when the width of the blade becomes WB, accessory hole buried portions 18b are placed at positions far away from the center of the scribe line by a distance equal to or longer than WB/2 distance. In this exemplary embodiment, the width (WB) of the blade becomes 30 to 50 μm. Accordingly, if the width of the blade becomes 30 μm, accessory hole buried portions 18b are placed at positions far away from the center of scribe line 24 by a distance equal to or longer than 15 μm. Meanwhile, with consideration of a positional deviation in the dicing process, it is preferable that accessory hole buried portions 18b are placed at positions further far away from the center of the scribe line.

Although in this exemplary embodiment, one accessory hole buried portion 18b is placed at each of both ends far away from the center of scribe line 24 when viewed from the top, a plurality of the accessory hole buried portions 18b may be placed at each of both ends far away from the center of scribe line 24. With employing the latter approach, it is possible to further prevent the accessory from peeling off.

A plurality of accessory hole buried portions 18b may be placed, when viewed from the top, in the extending direction of the scribe line. With employing such an approach, it is possible to further prevent the accessory from peeling off.

Although in this exemplary embodiment, the invention is applied to the accessory pattern disposed in the scribe line, the invention is not limited thereto. That is, the invention may be applied to any other accessory pattern which is formed in scribe line 24 using the third wire.

Although in this exemplary embodiment, the cap films on the pad 19 and the accessory are removed away, the cap films may remain as long as the inferior bonding ability may not appear.

Although in this exemplary embodiment, the accessory hole buried portions are disposed at both ends of the accessory, it may be effective that the accessory hole buried portion is placed only at one of both ends of the accessory, depending a given circumstance. For example, in case one end of both ends of the first portion is located at the center of the scribe line and the other is placed at a position far away from the center of the scribe line by a distance equal to or longer than WB/2 distance, it is effective that the accessory hole buried portion is placed only beneath the other end.

### Second Exemplary Embodiment

In the first exemplary embodiment, the tungsten plug is used in forming the third contact plug. In the second exemplary embodiment, the third wire to third contact plug are made of an aluminum alloy film in an integral manner.

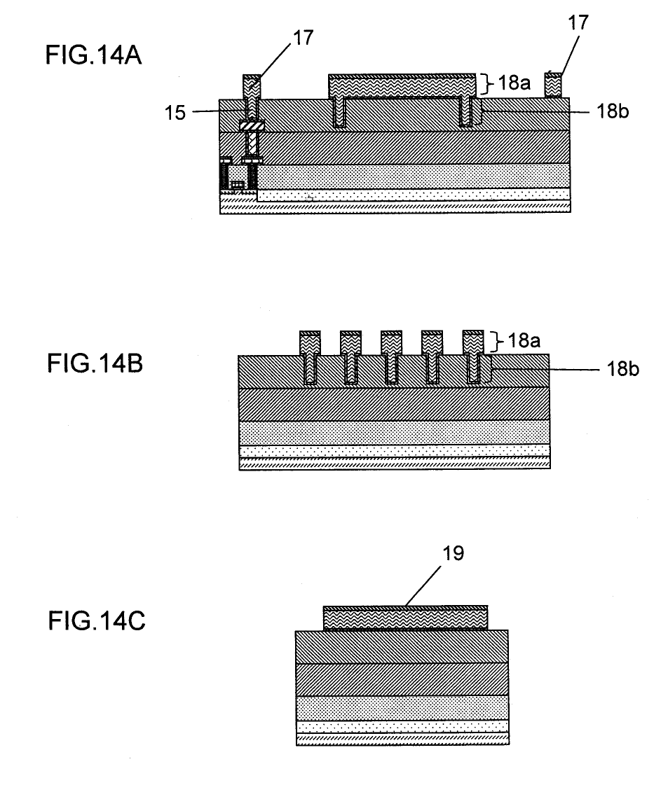

First, the processes from FIG. 1 to FIG. 5 in the first exemplary embodiment are carried out in the same way in the first exemplary embodiment. Next, a process as shown in FIG. 14 is preformed. FIGS. 14A, 14B, and 14C are cross-sectional views corresponding to FIGS. 12A, 12B and 13B respectively. As shown in FIG. 14, the third wire underlying layer is formed in the third contact hole and the accessory holes and on the third interlayer insulating film. The third wire underlying layer is made of a sequential stack of a titanium film, a titanium nitride film and a titanium film using a sputtering method. The thickness of the third wire underlying layer becomes 40 nm.

AlCu material is grown to form the third primary wire layer using a hot sputtering method so as to fill the holes. The hot sputtering method is carried out at 450° C. The thickness of the third primary wire layer becomes 1 rim. Then, the third cap layer made of a titanium nitride film is formed using the sputtering method. The thickness of the third cap layer becomes 50 nm. The third primary wire layer and the third primary wire layer form not only third contact plug 15 and accessory hole buried portions 18b but also third wire 17 and first portion 18a.

Third wire 17 connected to third contact plug 15, first portion 18a connected to accessory hole buried portions 18b and pads 19 are formed by patterning the third wire material using the photolithography and dry etching techniques in the same way as in the processes of FIGS. 7 and 8 in the first exemplary embodiment. In this manner, third wire 17 and third contact plug 15 are made of the aluminum alloy film in the integral way, and the third wire underlying layer is formed in an integral manner in such a way that the bottom of the third wire is integral to the side wall of the third contact hole.

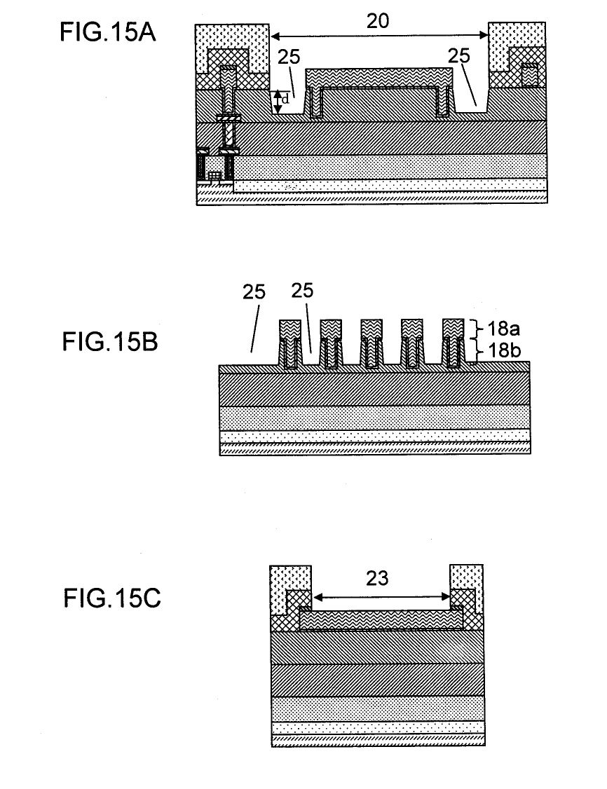

FIGS. 15A, 15B, and 15C are cross-sectional views corresponding to FIGS. 12A, 12B and 13B respectively. In the same way as in the processes of FIGS. 9 and 10 in the first exemplary embodiment, passivation film 21 and protective film 22 are formed and protective film 22 is etched away so that pad opening 23 and scribe line opening 20 are formed. In the same way as in the processes of FIG. 11 to FIG. 13 in the first exemplary embodiment, the passivation film etching is carried out to open the pad and at the same time form the depressed portion a (indicated as reference numeral 25 in the drawings) in the scribe line.

In accordance with the second exemplary embodiment, the third wire underlying layer is continuously formed from the bottom of the first portion through the side wall of the accessory hole to the bottom of the second portion and further the aluminum alloy film is continuously formed in the integrating manner of the first portion and the accessory hole buried portion. For this reason, the coupling between the first portion and the accessory hole buried portion becomes more rigid than in the first exemplary embodiment.

Although in the second exemplary embodiment, the hot aluminum sputtering method is employed in the way of example, the invention is not limited thereto but an aluminum reflow method may be used. Moreover, if the aspect ratio which is the depth to the diameter of the accessory hole is small and thus the aluminum material reaches into the holes easily using the conventional sputtering method, the conventional sputtering method may be employed to form the aluminum alloy film.

### Third Exemplary Embodiment

This third exemplary embodiment relates to a variation of the first exemplary embodiment. This exemplary embodiment is different from the first exemplary embodiment in that a fuse to be cut by irradiating the laser light thereto is formed using the first wire.

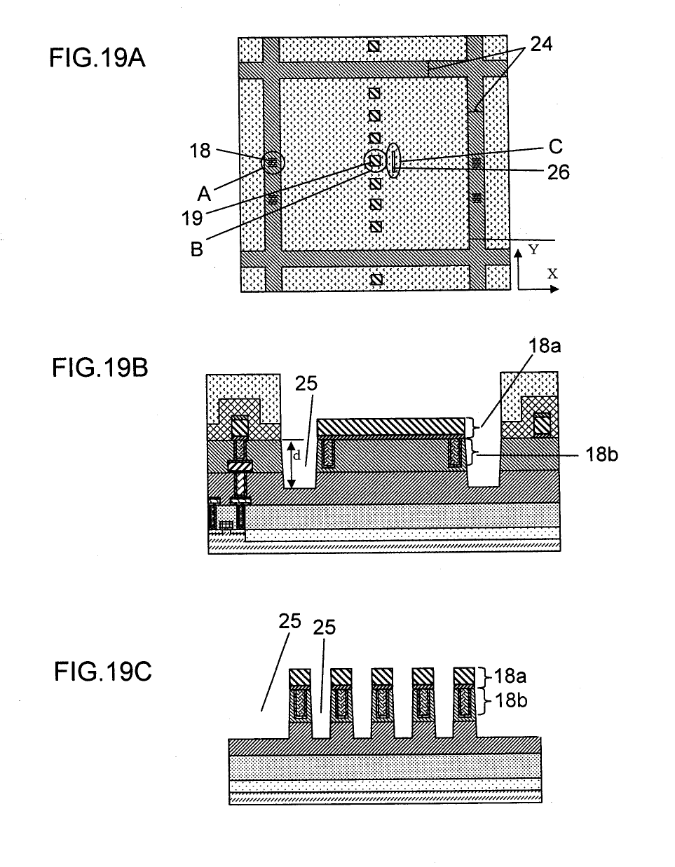

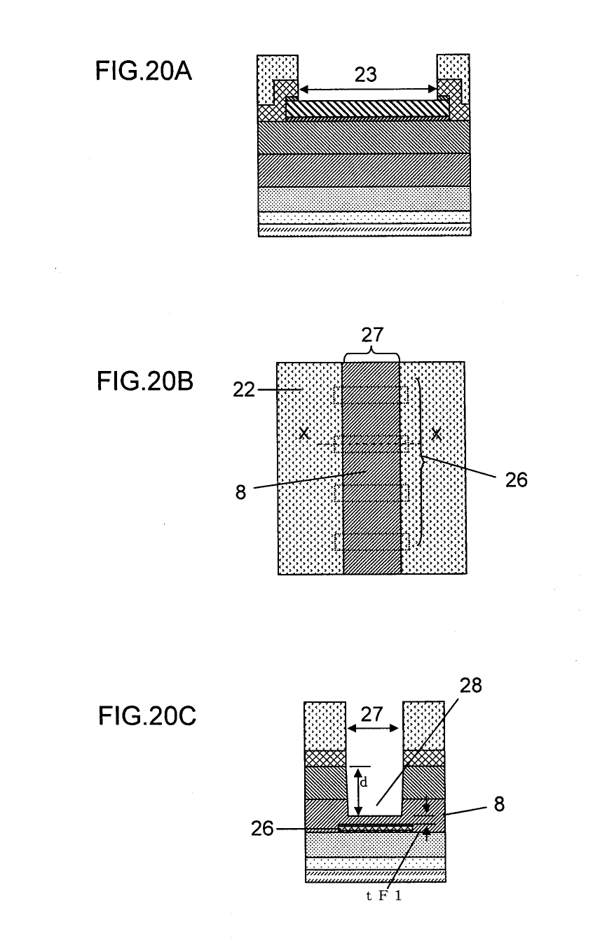

FIGS. 19 and 20 illustrate the semiconductor device according to the third exemplary embodiment of the invention. This exemplary embodiment includes the configuration of the first exemplary embodiment and a fuse forming region (indicated as region C) in the device forming region as shown in FIG. 19A. FIG. 20B is an enlarged top view of region C in FIG. 19A. Fuse opening 27 is formed in the protective film so as to extend in the width direction of the scribe line. In order to thin down the insulating film on fuse 26 and thus make it easy to cut the fuse, second interlayer insulating film 8 is exposed. A plurality of the fuses may be arranged in parallel to each other and in the direction perpendicular to the width direction of the scribe line.

FIG. 20C is a cross-sectional view in which fuse opening 27 in FIG. 20B is cut in the width direction of the scribe line and at the position in which the fuse exists. Second interlayer insulating film 8 remains with tF1 thickness on fuse 26 flush with the first wire and the insulating films thereon are removed away. Meanwhile, the contact plug and other wire layers connected to the fuse are omitted.

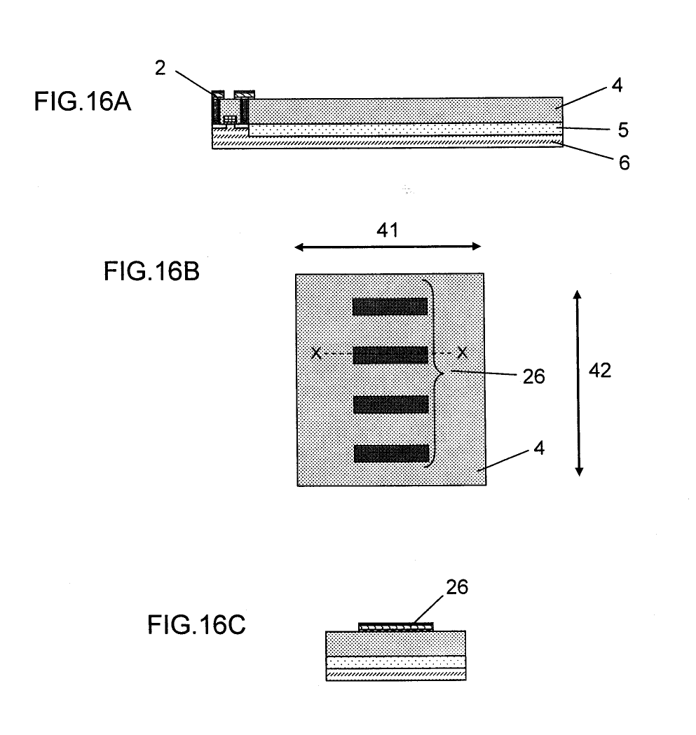

Below, a method for manufacturing the semiconductor device according to this exemplary embodiment will be described with reference to FIG. 16 to FIG. 20.

FIGS. 16A and 16B are drawings corresponding to FIGS. 19B and 20B respectively and FIG. 16C is a cross-sectional view taken in a line X-X in FIG. 16B. As shown in FIG. 16, the processes taken until the first contact plug and the first wire material in FIG. 1 have been formed in the first exemplary embodiment are carried out in the same way as in the first exemplary embodiment.

With the patterning of the first wire material, first wire 2 is formed in the same manner as in the first exemplary embodiment and at the same time the fuse is formed in the region corresponding to region C in FIG. 19A. FIG. 16B shows region C. When viewed from the top, fuse 26 has 6 μm size in width direction 41 of the scribe line and has 1 μm in perpendicular direction 42 to width direction 41. A plurality of fuses 26 are arranged in perpendicular direction 42 so as to be spaced from each other by 1 μm.

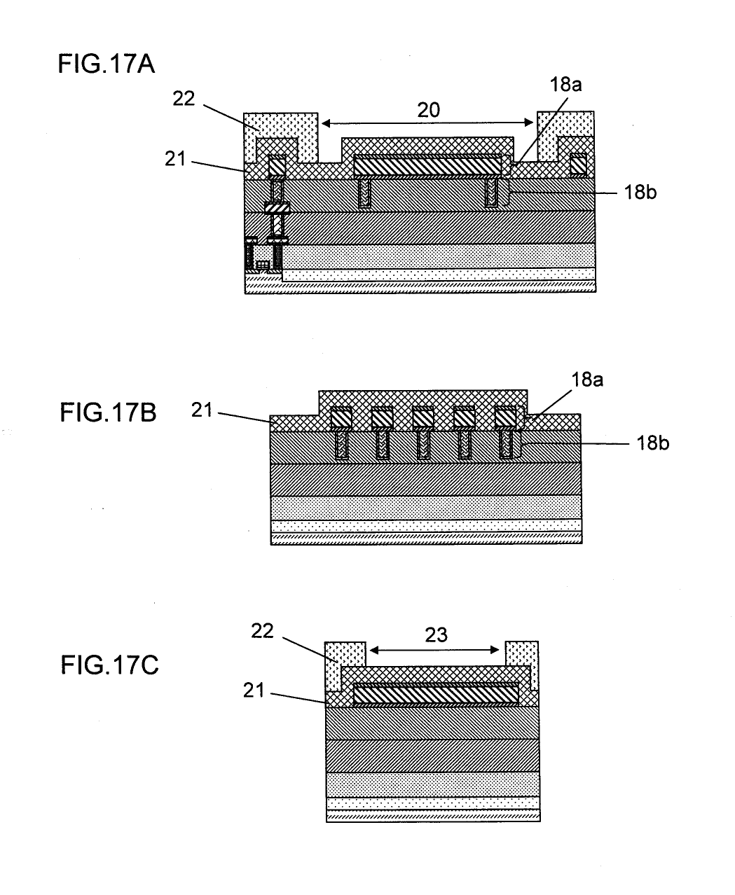

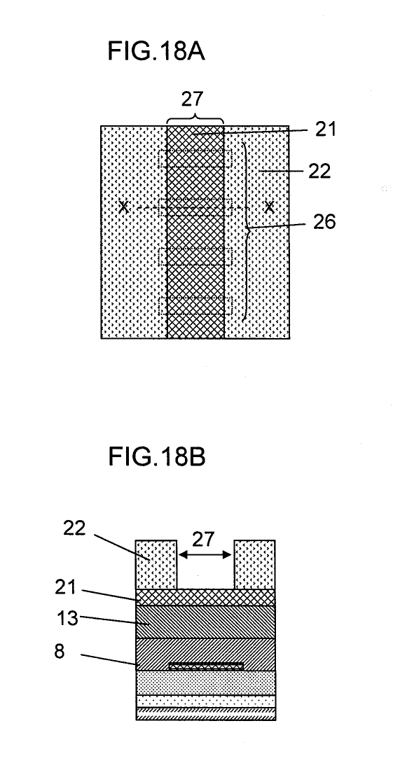

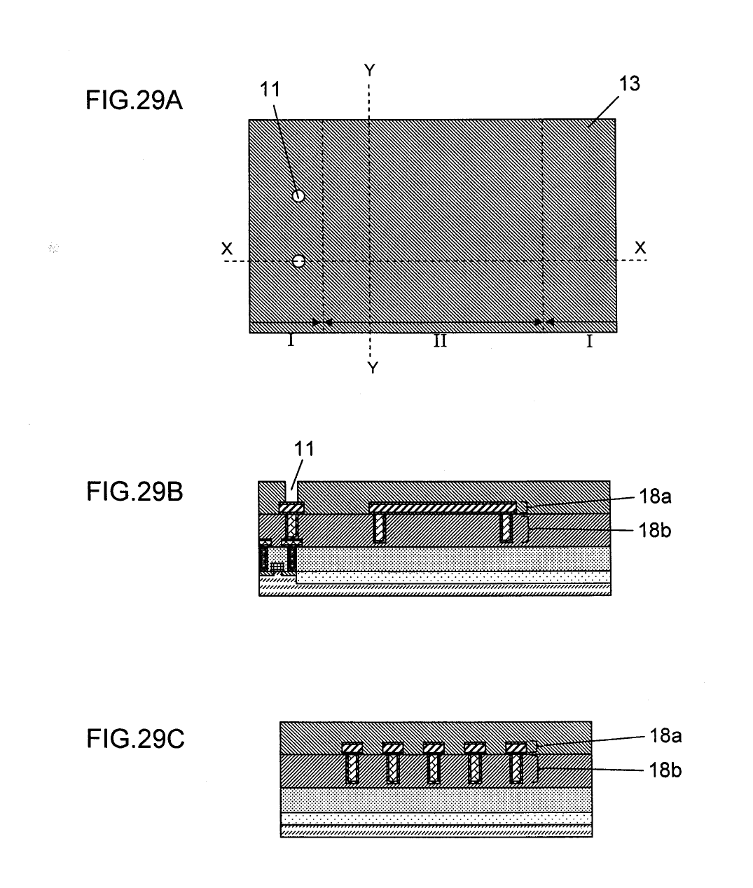

FIGS. 17A, 17B and 17C are drawings corresponding to FIGS. 19B, 19C and 29A respectively. FIG. 18A is a top view corresponding to FIG. 20B and FIG. 18B is a cross-sectional view taken in a line X-X in FIG. 18A.

The same processes as the processes of FIG. 2 to FIG. 8 in the first exemplary embodiment are carried out. Passivation film 21 and protective film 22 are formed in the same manner as in FIGS. 9 and 10 of the first exemplary embodiment. Openings 20, 23, and 27 are formed in protective film 22 in the same manner as in FIGS. 9 and 10 of the first exemplary embodiment. Regarding the formation of such openings 20, 23, and 27, pad opening 23 and scribe line opening 20 are formed in the same way as in the first exemplary embodiment and fuse opening 27 is additionally formed in region C as shown in FIG. 18A, resulting in forming these openings.

In FIG. 18A, fuses 26 not actually exposed from the surface are shown in an overlapping manner. Fuse opening 27 extends in perpendicular direction 42 to width direction 41 of the scribe line and is layout so as to open the central region of fuses 26 extending in width direction 41 of the scribe line. Second interlayer insulating film 8 is formed on fuses 26, third interlayer insulating film 13 is formed on film 8, passivation film 21 is formed on film 13 and protective film 22 is formed on film 21. Then, fuse opening 27 is formed in protective film 22.

The passivation film etching is carried out as in FIG. 9 of the first exemplary embodiment. The top face of pads 19 is exposed and accessory patterns 18 are exposed in the scribe line region (refer to FIGS. 19B, 19C, and 20A). As in the first exemplary embodiment, accessory hole buried portions (corresponding to the second portion) 18b are formed in the accessory pattern.

In this exemplary embodiment, etched amount of the insulating films is controlled in the passivation film etching so as to adjust thickness tF1 of the interlayer insulating film on the fuse. If thickness tF1 of interlayer insulating film 8 on fuses 26 is large, the cutting yield reduces in cutting fuse 26 using the irradiation of the laser light. Therefore, in order to improve the cutting yield, thickness tF1 of interlayer insulating film 8 on fuses 26 may be small. At this time, in case interlayer insulating film 8 on fuses 26 is completely removed away and thus fuses 26 are exposed, fuses may tend to be experiencing the corrosion. In this connection, it is necessary to control the remaining thickness in order not to expose the fuses.

In this exemplary embodiment, in FIG. 20C, thickness tF1 of remaining interlayer insulating film 8 on fuses 26 becomes 300 nm. In this way, the depth of depressed portion a (indicated as reference numeral 25 in the drawings) becomes larger than in the first exemplary embodiment, and hence depth d becomes approximately 1300 nm (refer to FIG. 20C).

Since the depth of depressed portion a becomes larger, the height of the pillar shape structure in accessory pattern 18 becomes approximately 2400 nm, thereby forming high level pillar. Accessory hole buried portions (corresponding to the second portion) 18b are formed in the accessory. Accordingly, the coupling force against the peeling off may be further enhanced.

Although in this exemplary embodiment, the third contact plug is made of the tungsten plug as in the first exemplary embodiment, the structure may be employed in which the wire and contact are made of the aluminum alloy material in the integral manner as in the second exemplary embodiment.

### Fourth Exemplary Embodiment

In the first to third exemplary embodiments, the aluminum alloy film is used as the first and second wires. In the fourth exemplary embodiment, a copper film is used as the first and second wires. The copper wire is formed using a damascene method.

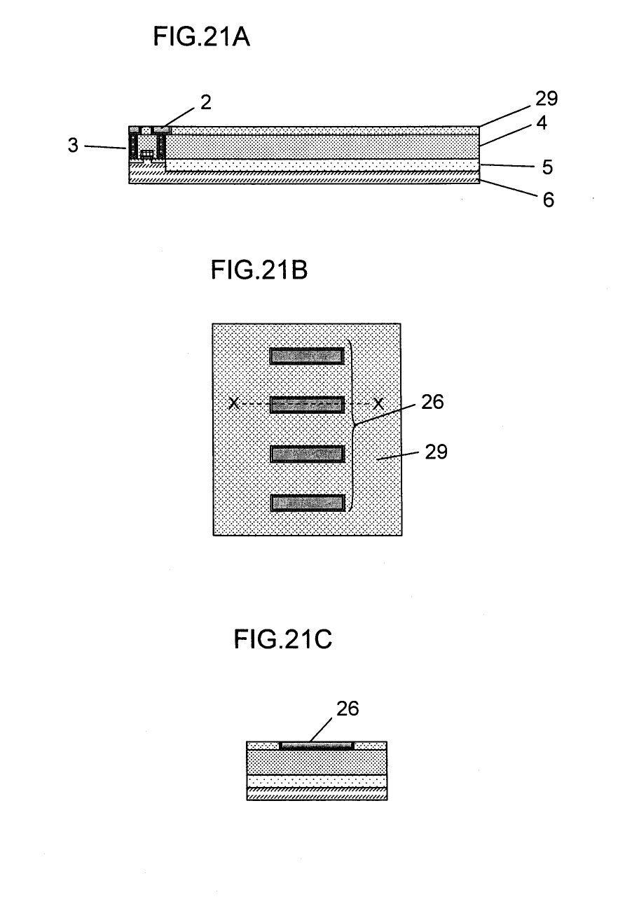

FIGS. 21A and 21B illustrate cross sections corresponding to FIGS. 19B and 20B in the third exemplary embodiment respectively. FIG. 21C is a cross-sectional view taken at a line X-X of FIG. 21B.

First, the processes taken until the first contact plug in FIG. 1 has been formed in the first exemplary embodiment are carried out in the same way as in the first exemplary embodiment.

Next, first intermediate insulating film 29 is formed on first contact plug 3 and first interlayer insulating film 4. A first wire groove is formed by removing first intermediate insulating film 29 at a region in which the first wire will be formed. A bottom portion of the first wire groove exposes the top face of first contact plug 3.

A titanium nitride film as a barrier metal and copper as a seed layer are formed in the first wire groove and on first intermediate insulating film 29 using the sputtering method to form a first underlying layer. A copper film is formed on the resulting structure using a plating method.

The copper film and the first underlying layer are polished and removed away using the CMP method to expose the top face of first intermediate insulating film 29. At this time, the copper film is buried in the first wire groove. In this way, there is formed in the first wire groove, first wire 2 including the first underlying layer and the first primary wire layer made of the copper film. The fuse groove is formed at the same time as in forming the first wire groove pattern. The fuse also is made of the copper film and the first underlying layer.

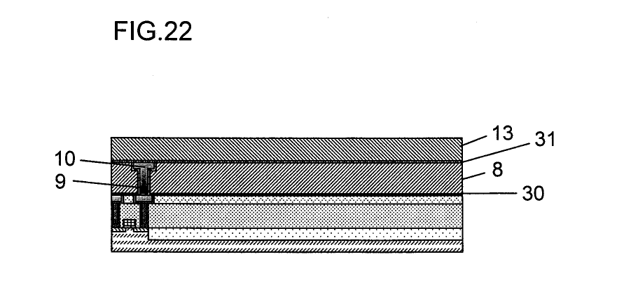

FIG. 22 illustrates a cross section corresponding to FIG. 16A in the third exemplary embodiment. First stopper layer 30 made of a silicon nitride (Si₃N₄) film is formed with 100 nm thickness. Otherwise, the material thereof may be SiCN.

Second interlayer insulating film 8 made of a silicon oxide film is formed thereon with 900 thickness. A second contact hole is formed so as to penetrate through second interlayer insulating film 8 and first stopper layer 30 and expose first wire 2.

A second wire groove for forming a second wire is formed by etching second interlayer insulating film 8. The second wire groove is connected to the second contact hole. A titanium nitride film as a barrier metal and copper as a seed layer are formed in the second contact hole and then the second wire groove and then on second interlayer insulating film 8 using the sputtering method to form a second underlying layer. A copper film is formed on the resulting structure using a plating method. The copper film and the second underlying layer are polished and removed away using the CMP method to expose the top face of second interlayer insulating film 8. At this time, the copper film is buried in the second contact hole and the second wire groove. In this way, there is formed in the second wire groove, second wire 10 including the second underlying layer and the second primary wire layer made of the copper film and at the same time there is formed second contact plug 9 which connects to the second wire and includes the second underlying layer and the copper film.

Second stopper layer 31 made of a silicon nitride (Si₃N₄) film is formed with 100 nm thickness. Otherwise, the material thereof may be SiCN. Third interlayer insulating film 13 made of a silicon oxide film is formed thereon with 900 thickness.

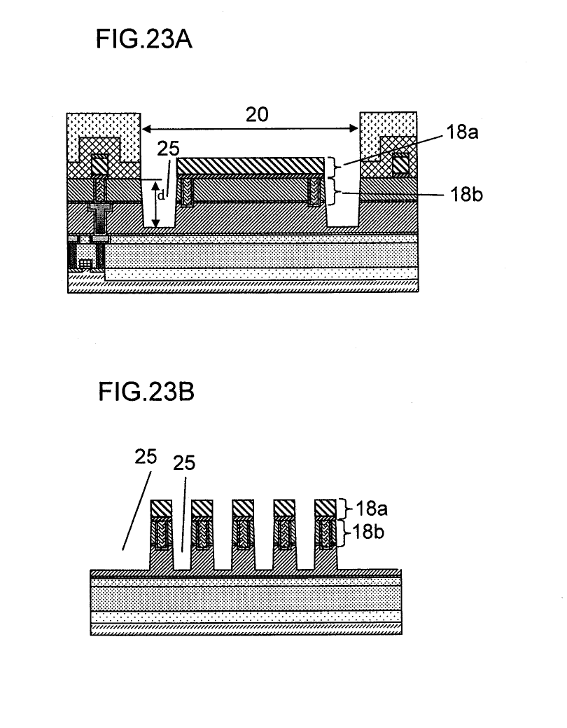

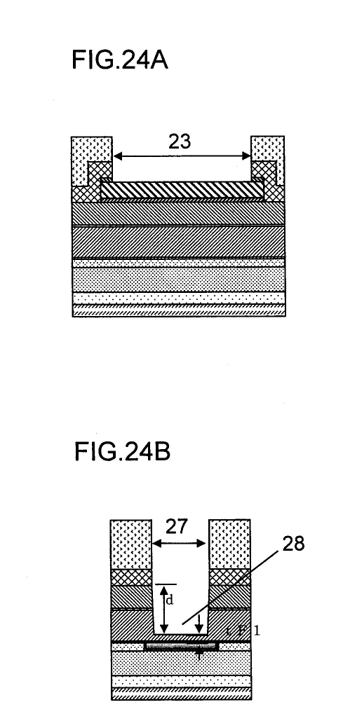

FIGS. 23A, 23B, 24A and 24B illustrate cross sections corresponding to FIGS. 19B, 19C, 20A and 20C in the third exemplary embodiment respectively.

The processes taken for the formation of third contact hole 11 and accessory holes 14 in FIG. 5 to the process of FIG. 8 in the first exemplary embodiment are carried out in the same way as in the first exemplary embodiment. Third wire 17 made of the aluminum alloy film is formed. This is because the copper film has inferior bonding ability with the pad. Thereafter, pad opening 23, scribe line opening 20 and fuse opening 27 are formed by performing the same processes as the processes of FIGS. 17, 19 and 20 in the third exemplary embodiment. Thickness tF1 and depth d are the same as in the third exemplary embodiment.

In this exemplary embodiment, fuse 26 may be made of the copper film. The wavelength and irradiation intensity of the laser light used in the cutting process may be selected depending on the material of the fuse.

### Fifth Exemplary Embodiment

In the first to fourth exemplary embodiments, the accessory is formed in the same process as in forming the third wire. In this fifth exemplary embodiment, the accessory is made of a layer under the third wire. That is, the accessory is made of the second wire and the fuse is made of the first wire.

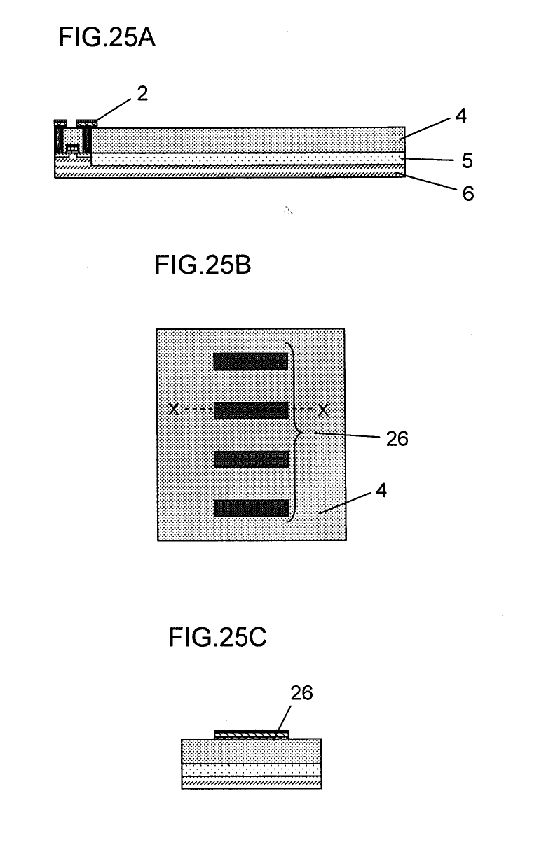

FIGS. 25A, 25B and 25C correspond to FIGS. 19B, 20B and 20C in the third exemplary embodiment respectively. As shown in FIG. 25, the processes taken up to the FIG. 16 in the third exemplary embodiment are carried out in the same way as in the third exemplary embodiment. The fuse is formed in region C using the first wire.

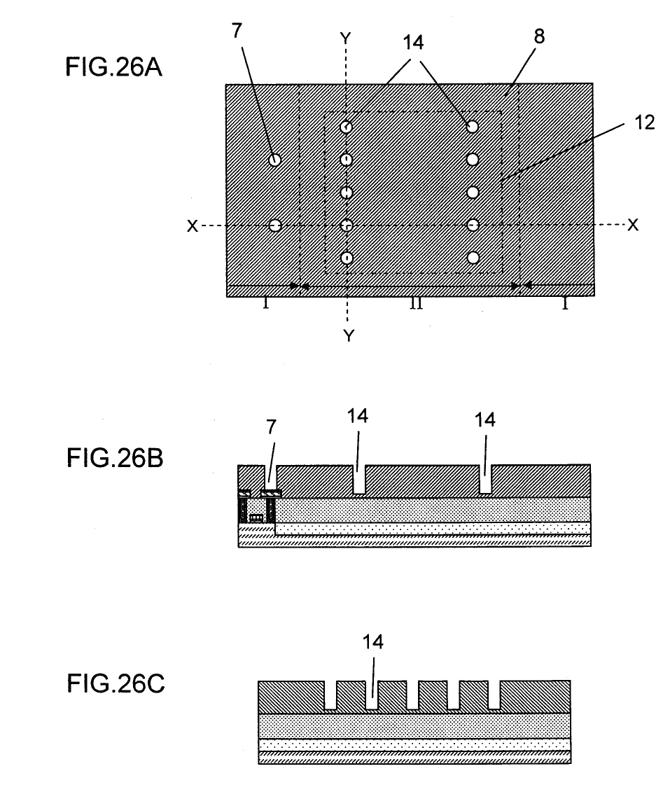

FIG. 26A is a top view of the resultant semiconductor device and FIGS. 26B and 26C are cross-sectional views taken at a line X-X and a line Y-Y in FIG. 26A respectively. As shown in FIG. 26, second interlayer insulating film 8 is formed in the same process as in FIG. 2 of the first exemplary embodiment.

Second contact hole 7 is formed in the same process as in FIG. 2 of the first exemplary embodiment. The forming of second contact hole 7 concurs with the formation of accessory holes 14 in the scribe line region. The etching carried out in forming second contact hole 7 becomes over-etching in which the top face of first wire 2 is exposed and thereafter further etching occurs in order to securely form second contact hole 7. Accordingly, accessory holes 14 are deeper than second contact hole 7 as shown in FIGS. 26B and 26C. The layout of second contact hole 7 and accessory holes 14 is substantially the same as that of third contact hole 11 and accessory holes 14 as shown in FIG. 5A of the first exemplary embodiment.

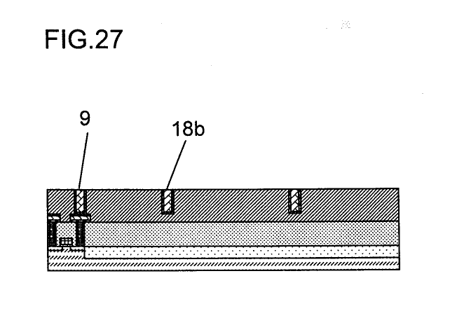

FIG. 27 is a cross-sectional view corresponding to FIG. 26B. As shown in FIG. 27, second contact plug 9 is formed in the same way as in FIG. 3 of the first exemplary embodiment. At the same time when second contact plug 9 is formed, accessory holes 14 are buried using the same material as in the second contact plug, thereby forming accessory hole buried portions (second portion) 18b.

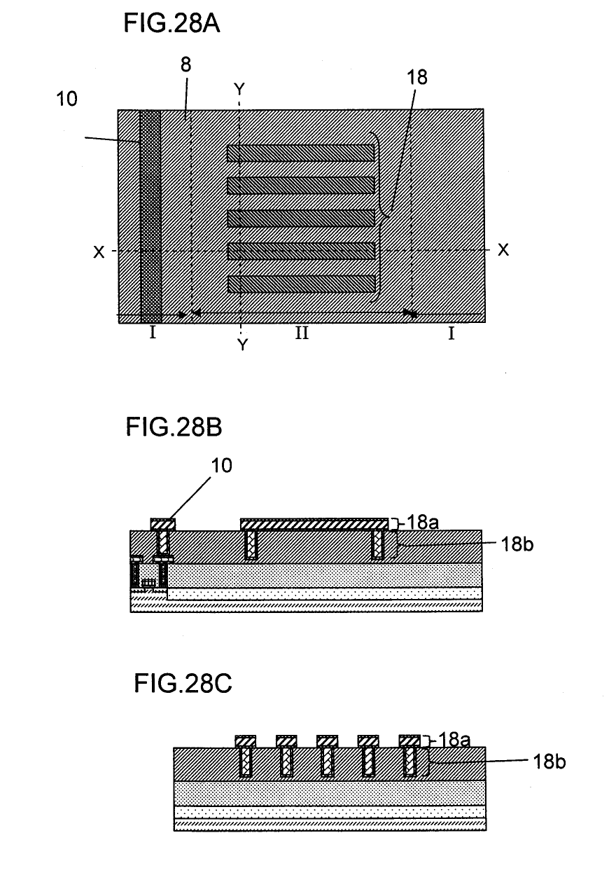

FIGS. 28A, 28B and 28C illustrate cross sections corresponding to FIGS. 26A, 26B and 26C respectively. As shown in FIG. 28, second wire 10 is formed in the same process as in FIG. 4 of the first exemplary embodiment. The formation of the second wire 10 concurs with the formation of first portion 18a. FIG. 28A is a top view of second wire 10 and accessory 18 in region A. The layout of second wire 10 and accessory 18 is substantially the same as that as shown in FIG. 7A of the first exemplary embodiment. The pad is formed in the processes of FIGS. 7 and 8 of the first exemplary embodiment but the pad is not formed in the same process as in forming the accessory in this exemplary embodiment.

In the accessory forming processes of FIGS. 7 and 8 of the first exemplary embodiment, the accessory hole buried portion is formed using the third contact plug and the first portion is formed using the third wire, whereas in this fifth exemplary embodiment, the accessory hole buried portion 18b is formed using the second contact plug and the first portion 18a is formed using the second wire. In the same manner as in the first exemplary embodiment, first portion 18a is supported with accessory hole buried portion 18b, thereby resulting in the accessory structure preventing the peeling off.

FIGS. 29A, 29B and 29C illustrate drawings corresponding to FIGS. 28A, 28B and 28C respectively. As shown in FIG. 29, third contact hole 11 is formed in the same process as in FIG. 5 of the first exemplary embodiment. FIG. 29A is a top view of region A. In this fifth exemplary embodiment, the accessory holes are not formed at the same time as in forming this third contact hole 11.

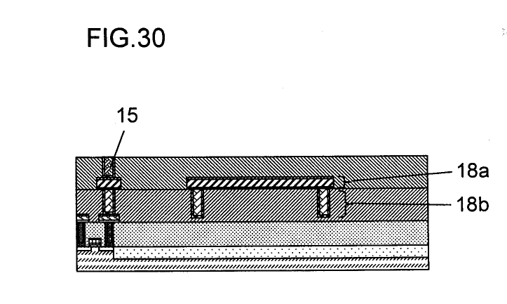

FIG. 30 is a cross-sectional view corresponding to FIG. 29B. As shown in FIG. 30, third contact plug 15 is formed in the same process as in FIG. 6 of the first exemplary embodiment.

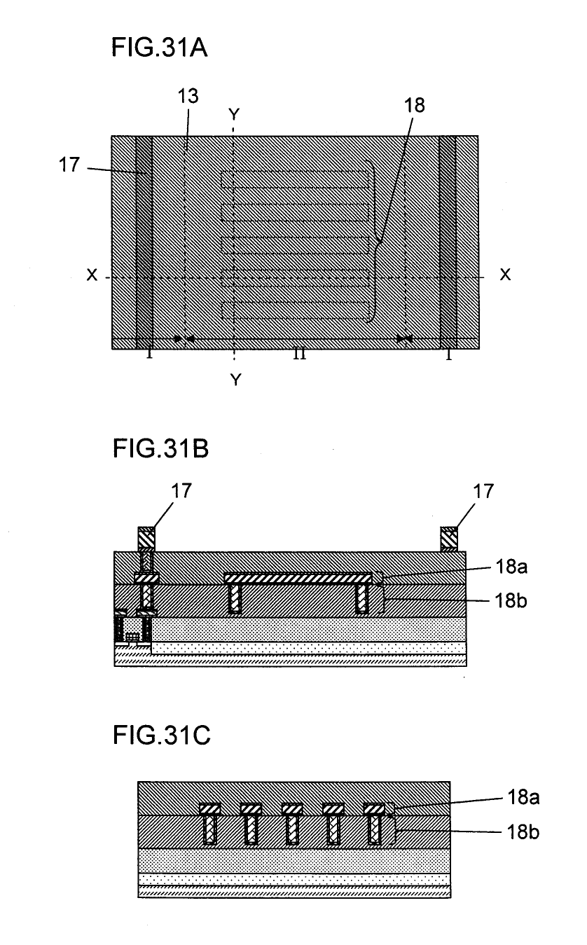

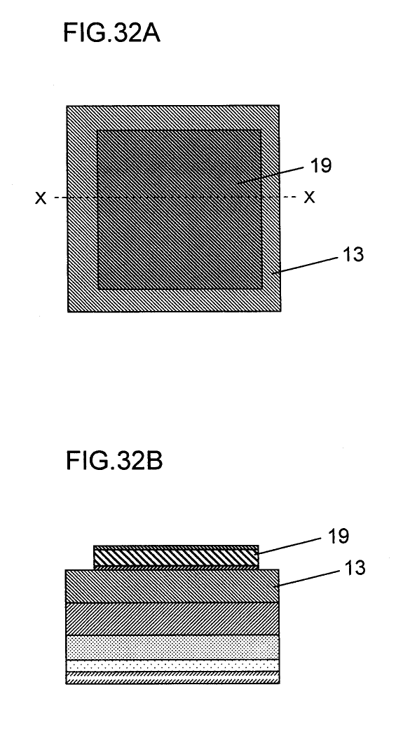

FIGS. 31A, 31B and 31C illustrate drawings corresponding to FIGS. 29A, 29B and 29C respectively. In FIG. 31A, the accessory not actually exposed from the surface is shown in an overlapping manner. FIG. 32A is a top view of region B in which the pad is formed; FIG. 32B is a cross-sectional view taken at a line X-X in FIG. 32A; and FIGS. 32A and 32B correspond to FIGS. 8A and 8B in the first exemplary embodiment respectively. As shown in FIGS. 31 and 32, third wire 17 is formed in the same process as in FIGS. 7 and 8 of the first exemplary embodiment. The formation of third wire 17 concurs with the formation of pad 19. However, the accessory is formed at the same time as in FIGS. 7 and 8 of the first exemplary embodiment, whereas the accessory is not formed as mentioned above in this process. Accessory 18 is buried under third interlayer insulating film 13.

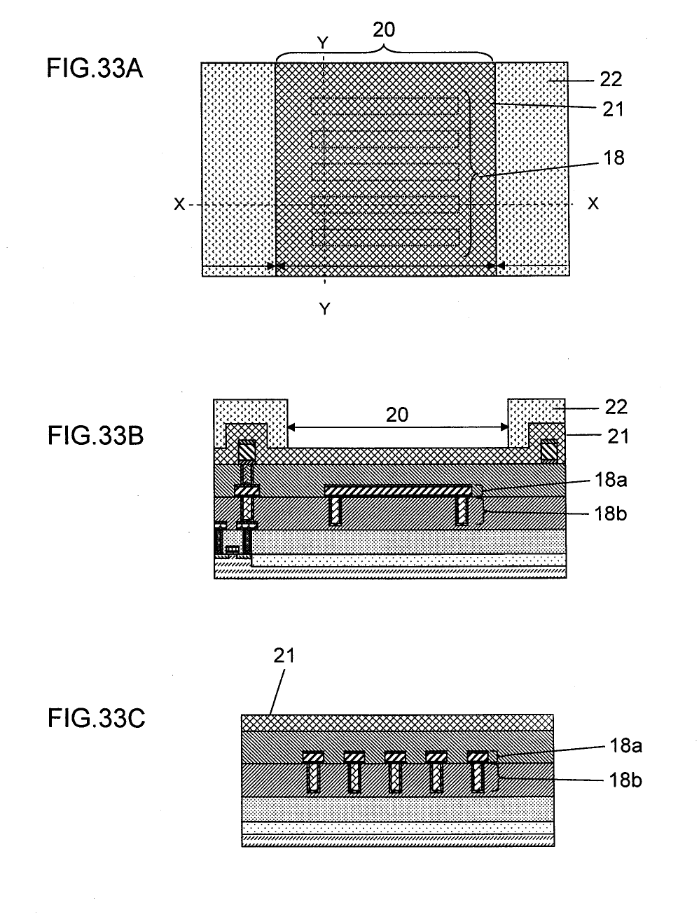

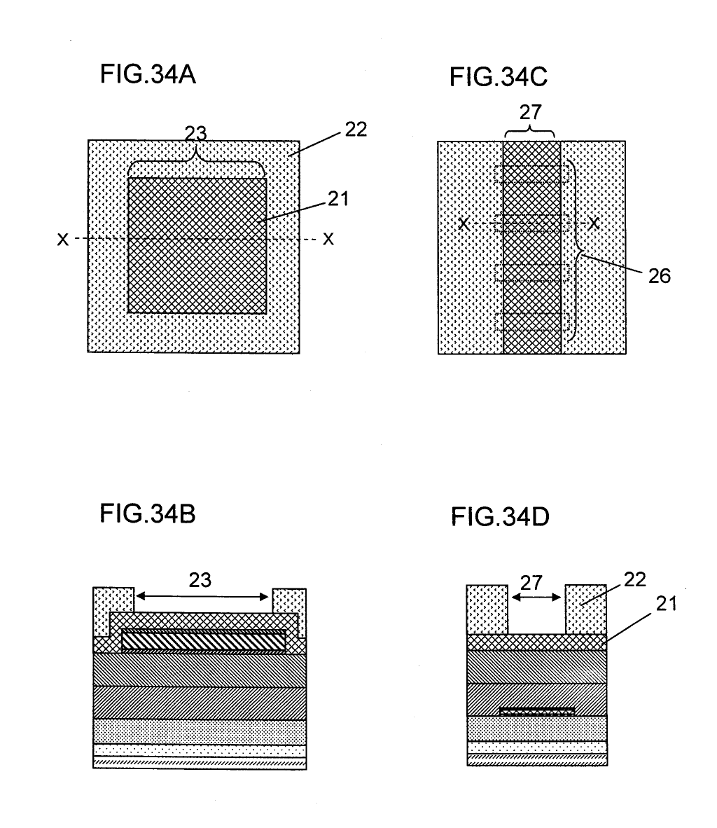

FIGS. 33A, 33B and 33C illustrate drawings corresponding to FIGS. 31A, 31B and 31C respectively. FIG. 34A is a top view of region B in which the pad is formed; FIG. 34B is a cross-sectional view taken at a line X-X in FIG. 34A; and FIGS. 34A and 34B correspond to FIGS. 8A and 8B in the first exemplary embodiment respectively. FIG. 34C is a top view of the region in which the fuse is formed; and FIG. 34D is a cross-sectional view taken at a line X-X in FIG. 34C. As shown in FIGS. 33 and 34, passivation film 21 and protective film 22 are formed and then pad opening 23, scribe line opening 20 and fuse opening 27 are formed by performing the same processes as the processes of FIG. 17 to FIG. 20 in the third exemplary embodiment.

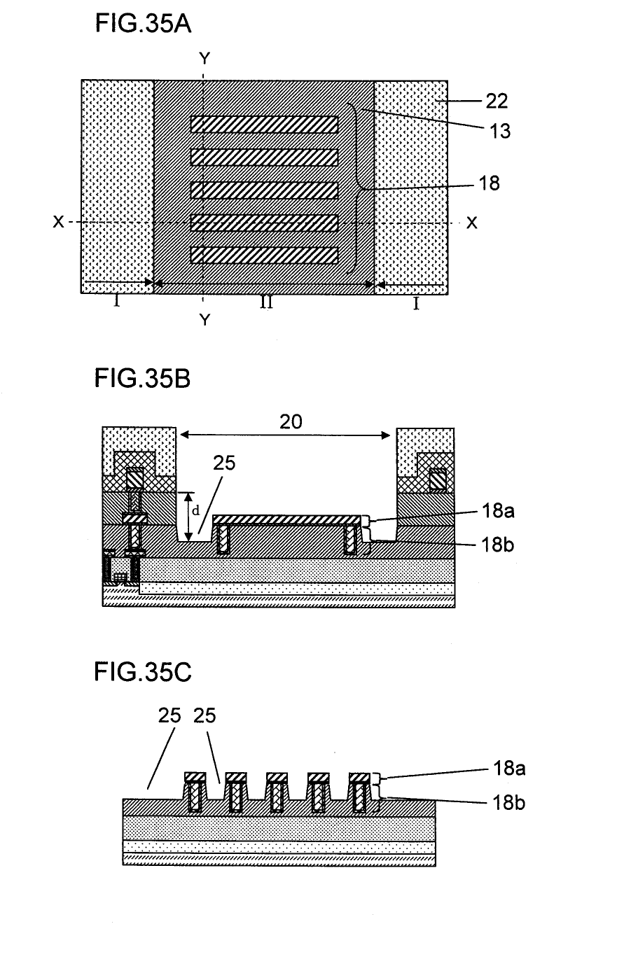

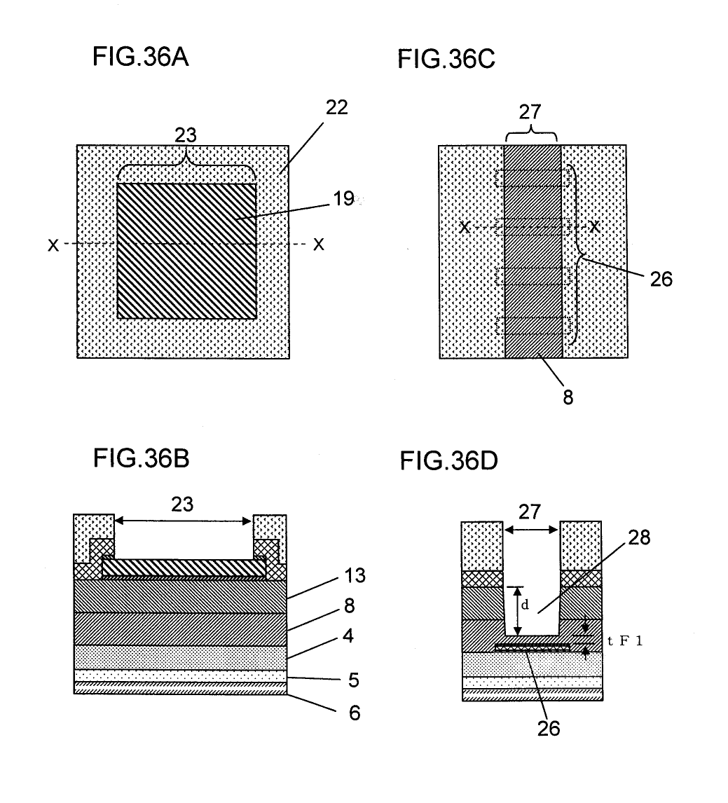

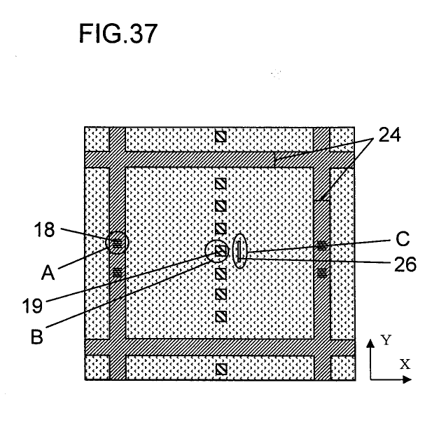

FIGS. 35A, 35B and 35C illustrate drawings corresponding to FIGS. 33A, 33B and 33C respectively. FIG. 36A is a top view of region B in which the pad is formed; FIG. 36B is a cross-sectional view taken at a line X-X in FIG. 36A; and FIGS. 36A and 36B correspond to FIGS. 8A and 8B in the first exemplary embodiment respectively. FIG. 36C is a top view of the region in which the fuse is formed; and FIG. 36D is a cross-sectional view taken at a line X-X in FIG. 36C. FIG. 37 is a top view of one region of the surface of the semiconductor substrate.

As shown in FIGS. 35 and 36, the passivation film etching is performed in the same process as in FIGS. 19 and 20 of the third exemplary embodiment. The insulating films are etched away so that second interlayer insulating film 8 on fuse 26 remains by tF1 thickness. Second and third interlayer insulating films 8, 13 are depressed away by depth d to form depressed portion a (indicated as reference numeral 25 in the drawings). Thickness tF1 and depth d become 300 nm and 1300 nm respectively as in the third exemplary embodiment. In this process, the top face and side face of the accessory formed at the same time as in forming the second wire are exposed and third interlayer insulating film 13 not protected with the accessory is depressed. The second cap film forming the upper portion of the accessory is removed away and thus the second primary wire layer is exposed.

In case in such a manner, the accessory is formed in the wire film under the topmost wire film, the accessory may be exposed if the etched amount of the interlayer insulating films may become larger in the scribe line region. Even in this case, since the layered first portion of the accessory is supported with the accessory hole buried portion of the accessory, the peeling off of the accessory may be suppressed and thus the reduction of the yield of the semiconductor device may be suppressed.

It is apparent that the present invention is not limited to the above embodiments, but may be modified and changed without departing from the scope and spirit of the invention.

In addition, while not specifically claimed in the claim section, the applications reserve the right to include in the claim section at any appropriate time the following method:
1. A method for manufacturing a semiconductor device, comprising:

forming an interlayer insulating film in a scribe line forming region of a semiconductor substrate;

forming a second portion so as to extend downward from a surface of the interlayer insulating film into the interlayer insulating film in a thickness direction thereof; and

forming a first portion with a layer shape on the interlayer insulating film so as to be in contact with the second portion, to provide an accessory including the first and second portions.
2. The method according to the above 1, further comprising:

forming a MOS transistor in a semiconductor chip region surrounded with the scribe line forming region of the semiconductor substrate;

forming a first contact plug connected to a source or drain region of the MOS transistor;

forming a first wire connected to the first contact plug;

forming a second contact plug connected to the first wire;

forming a second wire connected to the second contact plug;

forming a third contact plug connected to the second wire; and

forming a third wire connected to the third contact plug,

wherein the second contact plug is formed at the same time of formation of the second portion in the scribe line forming region, and

the second wire is formed at the same time of formation of the first portion in the scribe line forming region.
3. The method according to the above 1, further comprising:

forming a MOS transistor in a semiconductor chip region surrounded with the scribe line forming region of the semiconductor substrate;

forming a first contact plug connected to a source or drain region of the MOS transistor;

forming a first wire connected to the first contact plug;

forming a second contact plug connected to the first wire;

forming a second wire connected to the second contact plug;

forming a third contact plug connected to the second wire; and

forming a third wire connected to the third contact plug,

wherein the third contact plug is formed at the same time of formation of the second portion in the scribe line forming region, and

the third wire is formed at the same time of formation of the first portion in the scribe line forming region.
4. The method according to the above 2,

wherein in forming the first wire, the fuse is formed in the semiconductor chip at the same time of formation of the first wire.
5. The method according to the above 3,

wherein in forming the first wire, the fuse is formed in the semiconductor chip at the same time of formation of the first wire.

What is claimed is:

1. A semiconductor device comprising:
a semiconductor chip; and
a scribe line disposed around the semiconductor chip and comprising an interlayer insulating film and an accessory,
wherein the accessory comprises a first portion with a layer shape formed on the interlayer insulating film and a second portion extending downward from the first portion into the interlayer insulating film in a thickness direction thereof.

2. The semiconductor device according to claim 1,
wherein the first portion is made of different material from material of the second portion.

3. The semiconductor device according to claim 2,
wherein the first portion comprises a first underlying layer containing a titanium nitride film and a first metal layer formed sequentially on the interlayer insulating film, and
the second potion comprises a second underlying layer containing a titanium nitride film and formed on an inner wall of an accessory hole, and a second metal layer buried in the accessory hole.

4. The semiconductor device according to claim 3,
wherein the first underlying layer is made of the titanium nitride film or a titanium film/the titanium nitride film,
the first metal layer is made of an Al alloy film or an Al film containing Cu,
the second underlying layer is made of a titanium film/the titanium nitride film/a titanium film, and
the second metal layer is made of a W film, an Al alloy film, an Al film containing Cu, or a Cu film.

5. The semiconductor device according to claim 1,
wherein the first portion is made of the same material as material of the second portion.

6. The semiconductor device according to claim 5,
wherein the accessory comprises:
an underlying layer containing a titanium nitride film and formed continuously on a surface of the interlayer insulating film and an inner wall of an accessory hole; and
a metal film buried in the accessory hole and formed continuously from inside of the accessory hole to over the interlayer insulating film.

7. The semiconductor device according to claim 6,
wherein the underlying layer is made of a titanium film/the titanium nitride film/a titanium film, and
the second metal layer is made of a W film, an Al alloy film, an Al film containing Cu, or a Cu film.

8. The semiconductor device according to claim 1,
wherein the first portion extends in a width direction of the scribe line, and the second portion is disposed beneath one end of the first portion closer to the semiconductor chip in the width direction of the scribe line.

9. The semiconductor device according to claim 1,
wherein the accessory comprises a plurality of the second portions arranged in a width direction of the scribe line.

10. The semiconductor device according to claim 9,
wherein two second portions are arranged on both sides in the width direction of the scribe line.

11. The semiconductor device according to claim 1,
wherein the semiconductor chip comprises:
a MOS transistor;
a first contact plug connected to a source or drain region of the MOS transistor;
a first wire connected to the first contact plug;
a second contact plug connected to the first wire;
a second wire connected to the second contact plug;
a third contact plug connected to the second wire; and
a third wire connected to the third contact plug.

12. The semiconductor device according to claim 11,
wherein the second portion is made of the same material as material of the second contact plug,
the first portion comprises a layer made of the same material as material of the second wire, and
the first and second portions are flush with the second wire and second contact plug, respectively.

13. The semiconductor device according to claim 11,
wherein the second portion is made of the same material as material of the third contact plug,
the first portion comprises a layer made of the same material as material of the third wire, and
the first and second portions are flush with the third wire and third contact plug, respectively.

14. The semiconductor device according to claim 11,
wherein the semiconductor chip further comprises a pad,
the pad comprises a layer made of the same material as material of the third wire, and
the pad is flush with the third wire.

15. The semiconductor device according to claim 11,
wherein the semiconductor chip further comprises a fuse,
the fuse is made of the same material as material of the first wire, and
the fuse is flush with the first wire.

16. A semiconductor device comprising:
a semiconductor chip; and
a scribe line disposed in an adjacent way to and around the semiconductor chip and comprising an interlayer insulating film and an accessory,
wherein the accessory comprises a second portion buried in the interlayer insulating film and a first portion with a layer shape formed on the interlayer insulating film so as to be in contact with the second portion.

17. The semiconductor device according to claim 16,
wherein the first portion is made of different material from material of the second portion.

18. The semiconductor device according to claim 16,
wherein the first portion is made of the same material as material of the second portion.

19. The semiconductor device according to claim 16,
wherein two second portions are formed on both sides in the width direction of the scribe line.

20. A semiconductor device comprising:
a semiconductor chip; and
a scribe line disposed in an adjacent way to and around the semiconductor chip and comprising an interlayer insulating film and an accessory,
wherein the accessory comprises:
a first portion formed on the interlayer insulating film and extending in a width direction of the scribe line; and
two protruding second portions buried in the interlayer insulating film from both ends of the first portion in the width direction of the scribe line.
